(19) United States
(12) Patent Application Publication
(10) Pub. No.: US 2025/0354889 A1
(43) Pub. Date: Nov. 20, 2025

(54) SYSTEMS AND METHODS FOR DYNAMIC BRIDGE WEIGHT IN MOTION

(71) Applicants: Kaveh Arjomandi, Fredericton (CA); Ethan MacLeod, Fredericton (CA)

(72) Inventors: Kaveh Arjomandi, Fredericton (CA); Ethan MacLeod, Fredericton (CA)

(21) Appl. No.: 18/664,254

(22) Filed: May 14, 2024

(51) Int. Cl. G01M 5/00; G06F 30/13; G08G 1/01

(52) U.S. Cl. CPC G01M 5/0008; G01M 5/0041; G01M 5/0066; G06F 30/13; G08G 1/0116; G08G 1/0133

(57) ABSTRACT

System and method for monitoring vehicular traffic on a bridge, including receiving digital data representing the response of the bridge to a traffic event, where the digital data has been collected during the traffic event, from displacement sensors and accelerometers mounted on the superstructure of the bridge, wherein the digital data from the displacement sensors embody bending responses of the bridge, the digital data from the accelerometers embody acceleration responses of the bridge, and the digital data from the sensor are synchronised in the same time space, providing a parametric model which uses modal parameters to simulate generalized boundary conditions and two-dimensional behaviour of the bridge; using the parametric model to process the digital data to solve for deformation of the bridge and characteristics of the vehicle traffic, and generating an output that describes the deformation of the bridge and characteristics of the vehicle traffic.

### FIELD

In one of its aspects, the present disclosure relates generally to civil infrastructure monitoring, and bridge weigh in motion in particular.

### BACKGROUND

In Canada, the civil infrastructure in poor and very poor conditions has been estimated to have a replacement cost of $141 billion and is anticipated to keep increasing in the future (Canadian Society of Civil Engineers, 2016). In another report by the American Society of Civil Engineers (ASCE, 2021), approximately 7.5% of bridges in the United States were classified to be deficient in 2021. This has created a high demand for engineering tools that can accurately assess operational demands on bridge structures.

As the ratio of traffic demand to bridge capacity increases worldwide due to increased traffic loads and bridge degradation, oversize and overweight vehicles have become a regular challenge for bridge structures. Overweight trucks can cause serious damage to bridges and accelerate the degradation, causing fatigue problems and shortening service life. It is therefore essential to monitor the movement of heavy trucks on a bridge network for planning and maintenance. Currently, there is an increased interest in the development of real-time remote monitoring systems to determine the prevalence of overweight loading events and their impact on bridge structures.

Pavement based weighing systems have been in use for decades to enforce overloaded road traffic. The systems can be divided into three categories (Richardson et al., 2014):
1. Static: very accurate measurements but require vehicle be stationary on scales. These are typical at roadside weigh stations.
2. Low speed Weigh-In-Motion (WIM): still reasonably accurate and adequate for enforcement but require vehicles be travelling at speeds between 5-15 km/h.
3. High speed WIM: vehicles can maintain highway speed with the sensors typically imbedded into the highway surface. These systems are not accurate enough for enforcement but are typically used for preselection of vehicles to weigh at a static weigh station.

Though highly accurate, static and low speed WIM systems can be an ineffective form of widescale monitoring as they cause significant queuing and time delays. Conversely, pavement-based WIM systems can more efficiently monitor traffic and have been in use for decades to monitor and record road traffic. These systems work well for general measurement and classification of routine traffic travelling down main highways but are impractical for monitoring compliance of traffic passing over bridges. This is due to the large number of bridges in a transportation network and once a vehicle passes a WIM station there is no way to know which bridges it may pass over. Agencies have lacked a cost-effective mechanism to monitor these structures of concern as WIM stations are very costly and it would be impractical to construct a station at every bridge of concern.

This has resulted in the development of Bridge-Weigh-In-Motion (BWIM) systems to provide a more practical solution for bridge monitoring. Using an instrumented bridge as a scale, BWIM techniques estimate vehicle weights at full highway speeds (Moses, 1979). BWIM systems are more economical and are also more durable as they are not exposed to harsh road conditions such as snow and de-icing products as well as not being in direct contact with the traffic flow. Pavement-based sensors can only record a few milliseconds of the vehicle response due to the limited time the wheels are in contact with the sensors. Therefore, they are not sufficient to record a complete cycle of force oscillation, which results in errors in estimating the vehicle weight. BWIM systems, however, measure the complete time history of the bridge response, enabling more accurate estimation of the vehicle weights (Yu et al., 2016).

### BWIM Systems and Algorithms

BWIM is an inverse-type problem where the difference between the measured response and a theoretical response that is constructed using a calibrated influence line is minimized to calculate the axle weights of the vehicle. The main components of a classic BWIM system are shown in FIG. 1, consisting of (1) a data acquisition system, (2) event detection, (3) vehicle identification, and (4) weight estimation. Data acquisition typically consists of axle detection sensors that measure local effects of the vehicle axles and weighing sensors that measure the global response of a bridge subjected to operational traffic. These signals are used in event detection algorithms to determine when there is a vehicle loading event and produce a trimmed data segment that corresponds to the instance the first axle enters the bridge, until the final axle exits the bridge. The local event data segment is then used for vehicle identification, which consists of estimating the velocity and the vehicle axle spacing.

These vehicle parameters, along with the global events and the influence line or surface are the inputs in the weighing algorithm to determine the vehicle axle weights. Influence lines (IL) or influence surfaces (IS) are inherent properties of a bridge structure and to accurately estimate them the analytical function must be calibrated using the response of the structure subjected to calibration vehicle(s) with known parameters. Significant developments in BWIM systems have occurred in recent years, with several successful full-scale installations reported in the literature (Lydon et al., 2016; Yu et al., 2016). FIG. 1 is a diagram of data flow in a prior art BWIM system.

Traditional methods of vehicle identification performed axle detection with tape switches and pneumatic tubes. The installation of the axle detectors directly on the pavement was challenging, however, as it required the closure of traffic lanes for installation and proved to have poor durability (Kalin et al., 2006). To overcome the problems of these traditional methods, the Free-of-Axle Detector (FAD) method was first proposed in the Weigh-in-Motion of Road Vehicles for Europe (WAVE) project (WAVE, 2001). FAD sensors are typically strain gauges which are installed beneath the bridge deck at the quarter and three-quarter points of the spans to measure the bending strains locally (Kalin et al., 2006). Short span bridges or bridges with secondary elements such as orthotropic decks are ideal choices for FAD systems as they isolate the local strain from the global behaviour of the structure (Kalin et al., 2006; Zhao et al., 2014). Recently, various sensing technologies have been introduced to improve the detection of axles and spacing estimation such as fiber optical sensors (Lydon et al. 2017), a roadside camera (Ojio et al., 2016), microphones (Algohi et al., 2018) and microelectromechanical systems (MEMS) accelerometers (Mustafa et al., 2020; Sekiya, 2019; Sekiya et al., 2018).

Most current axle detection methods are limited to short-span bridges (Kalin et al., 2006; Zhao et al., 2014). In long span bridges or bridges with thick slabs or superstructures, the global behaviour of the structure can obscure the peaks in the axle detection signals generated by the individual axles and only present the joint contribution of closely spaced axles. Large long-span bridges can also result in poor axle detection as it is difficult to ensure the sensor is under the wheel path for all lanes and that the response is sensitive enough to the wheel loading, especially in the case of beam and slab bridges (S. Ieng et al., 2012).

BWIM weighing algorithms can be divided into two classes: (1) static methods that estimate the equivalent static axle weights without considering the dynamic components of the bridge response and; (2) dynamic methods that estimate the time history of the axle forces by considering the vehicle-bridge dynamic interaction. Traditional BWIM methods are static and based on the early work of Moses (Moses, 1979). The Moses algorithm estimates the vehicle axle weights by minimizing the difference between the measured bridge response and the predicted bridge response, which is calculated using the estimated static influence line of the bridge. Influence lines represent the variation in a function such as moment or deflection at a specific point in a member as a concentrated unit force modes along the member (Hibbeler, 2018). The Moses algorithm assumes that the bending in the bridge

$${M}_{A}^{th}$$

is proportional to the product of the magnitude of the applied moving load W and the influence line ordinate of the bridge I which is shown schematically in FIG. 2. The early influence lines employed in the Moses algorithm were purely theoretical and lacked accuracy in predicting the real behaviour of a bridge (Zhao et al., 2015).

FIG. 2 is a schematic diagram of a conventional BWIM system using static influence lines (Jacob, 1999). Therefore, to improve the accuracy of influence line estimation, researchers have developed alternative methods for modifying theoretical influence lines using measured data from calibration vehicle trials. A point-by-point graphical method to improve the theoretical influence line was developed by McNulty and O'Brien (McNulty & O'Brien, 2003), however, this method was dependent upon the skill of the operator. O'Brien et. al. (O'Brien et al., 2006) overcame this limitation by developing a method for estimating the influence line from direct measurement when the bridge is loaded using a vehicle with known axles. More recently, probabilistic methods have shown promise with a method using the maximum likelihood principle introduced by Ieng (S.-S. Ieng, 2015) and a method developed by O'Brien et. al. (O'Brien et al., 2018) which assumes each influence line ordinate follows a normal.

The accuracy of the static Moses algorithm is significantly affected by a number of factors including the transverse position of the vehicles and the dynamic effects of moving vehicles (Yu et al., 2016). The traditional Moses algorithm considers the bridge as a beam and therefore does not account for the transverse position of the vehicle on the bridge (O'Brien et al., 1999). To address this shortcoming, Quilligan (Quilligan, 2002) developed a two-dimensional influence surface approach which was later expanded by Zhao et. al. (Zhao et al., 2014) by including the effects of transversely distributing wheel loads on the individual girders.

It is widely reported that the dynamic vehicle-bridge interaction is the largest source of error, especially in larger medium- and long-span bridges where the increased dynamic effects of moving vehicles pose a significant problem for the Moses algorithm and affect the accuracy (Jacob & O'Brien, 1998). This has led to the development of BWIM methods that consider the dynamic characteristics of the vehicle-bridge interaction which primarily rely on moving force identification (MFI) methods. MFI methods solve for the complete time history of a vehicle axle force that minimizes the difference between the measured bridge response and dynamic simulations. Classical MFI methods relied on simplified beam models with the earliest adaptation to BWIM being the Interpretive Method (IM) which used a lumped mass (O'Connor & Chan, 1988) and Euler Bernoulli beam (Chan et al., 1999). Law et. al. developed a Time Domain Method (TDM) (Law et al., 1997) to perform MFI by using modal superposition in the time domain, and the Frequency Time Domain Method (FTDM) (Law et al., 1999) to evaluate the bridge response in the frequency domain to use for axle forces identification.

Previous research shows that for accurate simulation of vehicle loading on bridge systems, simple beam models fall short as they cannot adequately represent the full three-dimensional torsional and transverse behaviour of the bridge, which may have significant contributions to the response. Therefore, the MFI methods based on oversimplified bridge models consisting of beams may not accurately reflect the true behaviour of the complex three-dimensional bridge structure due to many necessary simplifications and assumptions (Richardson et al., 2014). To address this, further improvements were made to MFI methods to improve their axle weight identification accuracy by considering more realistic bridge models. González et. al. (González et al., 2008) developed an improved method using a two-dimensional orthotropic plate bridge model. This method was extended to a three-dimensional finite element model and an eigenvalue reduction technique (Rowley et al., 2009). Using the principle of superposition and an influence surface, Deng and Cai (Deng & Cai, 2010) suggested an alternative MFI method that considers a three-dimensional bridge model. These more advanced models face a significant challenge as it is necessary to use a calibrated finite element model of the bridge to use the MFI methods for BWIM. A method developed by Dowling et. al. (Dowling et al., 2012) performs a calibration of the model used in the MFI algorithm using the Cross-Entropy (CE) method of optimization.

Though MFI methods have the potential to be very accurate for BWIM, there are still significant challenges in implementing these methods in a real-world setting. MFI methods are computationally expensive and complex; therefore, it can be difficult to achieve the real-time identification of axle weights (Yu et al., 2016). As a result, the majority of BWIM systems currently in operation rely on static methods and assumptions rather than potentially more accurate dynamic systems (Carraro et al., 2019).

For BWIM to be an effective tool for overweight vehicle enforcement, it must be viable for relatively long and flexible girder-slab-type bridges which are very common in Canada and North America. To address the current deficiencies of traditional methods and create a viable BWIM solution for these common bridge types is desired.

### SUMMARY

The present disclosure in one aspect relates to a bridge weigh-in-motion (BWIM) method that considers the dynamic response of the bridge. This is achieved through the design and deployment of a long-term, full scale monitoring system on an arterial highway bridge. The monitoring system was designed to perform traditional BWIM while being augmented with accelerometers to perform vibration monitoring. The inclusion of accelerometers enables the inclusion of hybrid sensor data into both vehicle identification and weighing algorithms.

In certain embodiments, the developed components enables the present method to address three key problems faced by current BWIM methods, which are summarized as follows:
1. Current vehicle identification methods are limited to short-span bridges. To address this, a robust vehicle identification algorithm suitable for long and flexible bridge structures was developed. The result was a novel acceleration-based vehicle identification method employed within a hybrid bridge-weigh-in-motion (BWIM) system in which the traditional strain-based BWIM system is augmented with an array of accelerometers.
2. Simple beam models cannot adequately represent the full two-dimensional torsional and transverse behaviour of a bridge subjected to vehicle loading. To address these limitations, a novel two-dimensional vehicle-bridge interaction (VBI) model was developed that is valid for any generalized structural system and arbitrary boundary conditions. By using the experimentally estimated modal parameters of the structure, the method requires no complex FE models or cumbersome analytical mode shape solutions. A two-dimensional sprung mass vehicle model is considered and the addition of a road roughness profile to the bridge is included.
3. Dynamic vehicle bridge interaction is the largest source of error in current commonly employed static BWIM methods. For dynamic BWIM systems to be deployed as practical and viable real-time enforcement tools, the computational complexity of current MFI and FE methods must be reduced. A dynamic parametric BWIM method is presented that builds on the VBI model to simulate the response of a two-dimensional bridge structure to a moving load. The VBI simulation and dynamic BWIM method are compared in FIG.
3. Though both methods use modal parameters to simulate generalized boundary conditions and two-dimensional bridge behaviour, the BWIM method simplifies this framework to include a moving mass vehicle model and the mode shapes are represented parametrically as a Fourier series, which enables a closed-form solution and results in a system with comparable computational efficiency as current simplified static methods.

FIG. 3A is a schematic diagram of a VBI simulation method as compared with FIG. 3B, which is a schematic diagram of a dynamic BWIM method. The VBI model is then reformulated to allow for the estimation of vehicle parameters using the measured bridge response. This method augments the classical system with the inclusion of estimated modal parameters which are then used in the weighing algorithm and in the calculation of the influence surface as highlighted in FIG. 4.

In one aspect, the present disclosure relates to an analytical vehicle-bridge simulation method using plate vibration theories and experimentally estimated modal parameters.

The simulation method is valid for any generalized structural system and boundary conditions because this method utilizes the structure's modal parameters extracted experimentally using ambient vibration data and operational modal analysis, meaning there is no need for calibrated FE models or cumbersome analytical modal analysis solutions.

In another aspect, unlike simple beam models, the method can capture the full two-dimensional response of the structure as the estimated modes inherently capture the torsional and transverse behaviour of the whole structure.

In another aspect, a sprung mass vehicle model and road roughness is included in the method and therefore allows for the direct analysis of the vehicle response.

It was found that by using the method according to an aspect of the present disclosure and the estimated linear mode shapes, that the approximate response can accurately be estimated at the traffic path if it coincides with the sensor locations. This highlights the importance of considering the full three-dimensional behaviour of the structure as the estimated linear modes, which can accurately describe longitudinal bending, do not adequately capture the bridge transverse nonlinear behaviour. As a result, a fine sensor network is recommended to accurately describe the full response of the bridge transversely. Excellent agreement between the measured and estimated response was achieved when using the expanded mode shapes which captured nonlinear transverse bending. It was also shown that it is important to account for the contribution of higher modes as using an insufficient number of modes may result in overestimation or underestimation of the bridge response.

The present disclosure demonstrates that road roughness and vehicle suspension dynamics can have significant effects on the response of the structure even if the vehicle mass is much less than the bridge mass. This is in contrast with some previous research. The findings of the present inventors are that in cases where the vehicle to bridge displacements are relatively large, accounting for the vehicle dynamics is essential. This condition can be present in concrete highway structures with poor pavement conditions.

In another aspect, the present disclosure relates to an extension of the bridge-vehicle interaction model to a bridge weigh-in-motion method and system that can be used for real-time traffic monitoring applications in full-scale highway bridges.

To address the current limitations of BWIM, a novel dynamic parametric BWIM method is presented that utilizes the experimentally estimated modal parameters of the bridge structure to simulate its response subjected to moving traffic loads.

In one aspect, the present disclosure relates to a computer-implemented method for monitoring vehicular traffic on a bridge, including the steps of receiving digital data representing the response of the bridge to a traffic event on the bridge, where the digital data has been collected during the traffic event from displacement sensors and accelerometers mounted on the superstructure of the bridge, wherein the digital data from the displacement sensors embody bending responses of the bridge, the digital data from the accelerometers embody acceleration responses of the bridge, and the digital data from the displacement sensors and the digital data from the accelerometers are synchronised in the same time space, providing a parametric model which uses modal parameters to simulate generalized boundary conditions and two-dimensional behaviour of the bridge; using the parametric model to process the digital data to solve for deformation of the bridge and characteristics of the vehicle traffic, and generating an output that describes the deformation of the bridge and characteristics of the vehicle traffic.

In one aspect, the present disclosure relates to a system monitoring of vehicle traffic on a bridge, including displacement sensors and accelerometers mounted on the superstructure of the bridge and configured to collect digital data associated with a bending response and acceleration response of at least a part of the superstructure, a data acquisition module for receiving the digital data and a computer processing module programmed with instructions to solve a parametric model which uses modal parameters to simulate generalized boundary conditions and two-dimensional behaviour of the bridge to process the digital data to solve for deformation of the bridge and characteristics of the vehicle traffic, and an output module for generating an output that describes the deformation of the bridge and characteristics of the vehicle traffic.

### BRIEF DESCRIPTION OF THE DRAWINGS

Embodiments of the present invention will be described with reference to the accompanying drawings, wherein like reference numerals denote like parts, and in which:

FIG. 1 is a diagram of data flow in a prior art BWIM system;

FIG. 2 is a schematic diagram of a conventional prior art BWIM system using static influence lines;

FIG. 3A is a schematic diagram of a VBI simulation method;

FIG. 3B is a schematic diagram of a dynamic BWIM method;

FIG. 4 is a diagram of data flow in a BWIM system as well as addition of estimated modal parameters to the weighing algorithm and parametric model calibration according to an embodiment of the present invention;

FIG. 5 is a photograph of the W475 Westfield overpass;

FIG. 6A is a plan view of the W475 Westfield overpass;

FIG. 6B is an elevation view of the W475 Westfield overpass;

FIG. 6C is a typical deck cross section;

FIG. 7 is a satellite image showing orientation and ramps of the bridge chosen for instrumentation;

FIG. 8 is a diagram that shows sensor placement, including weighing and axle detection sensors as well as accelerometers;

FIG. 9A is a graph that shows vehicle velocity estimation using acceleration data for a peak to peak method;

FIG. 9B is a graph that shows vehicle velocity estimation using a correlation method;

FIG. 10 is a graph that shows time lag between peak accelerations in sensors A1 to A4;

FIG. 11A is a graph that shows cumulative time lags, 95% confidence intervals, and probability density functions for southbound vehicles;

FIG. 11B is a graph that shows cumulative time lags, 95% confidence intervals, and probability density functions for northbound vehicles;

FIG. 12 shows an illustrative example of acceleration for a) raw time domain, b) raw frequency domain, c) filtered time domain, and d) filtered frequency domain;

FIG. 13 shows a stabilization diagram;

FIG. 14 shows diagrams of the first eight estimated mode shapes, frequencies and damping ratios;

FIG. 15 is an illustrative example of signals a) after bandpass filter, and b) after moving average;

FIG. 16 contains graphs that show filtered acceleration signal segments for a) entering the bridge, and b) exiting the bridge;

FIG. 17A is a diagram that shows vehicle bridge interaction models with three-dimensional arrangement;

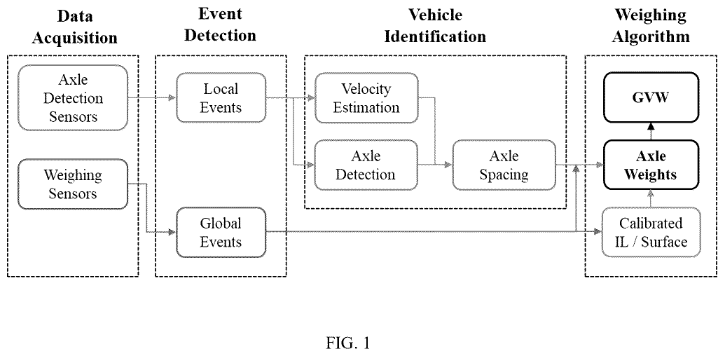

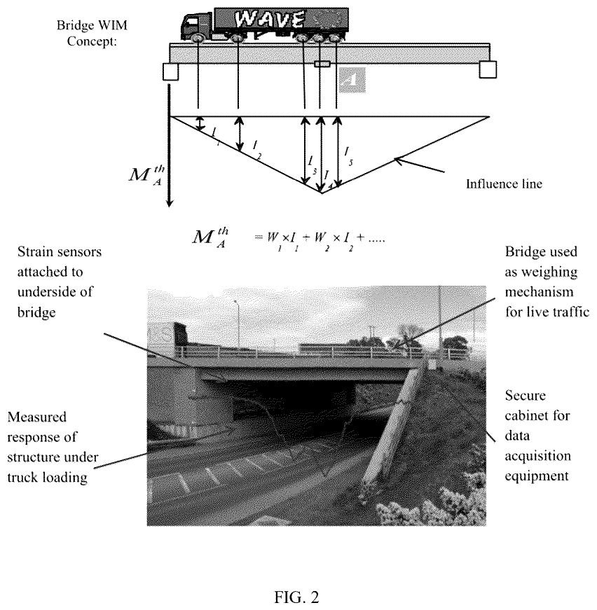

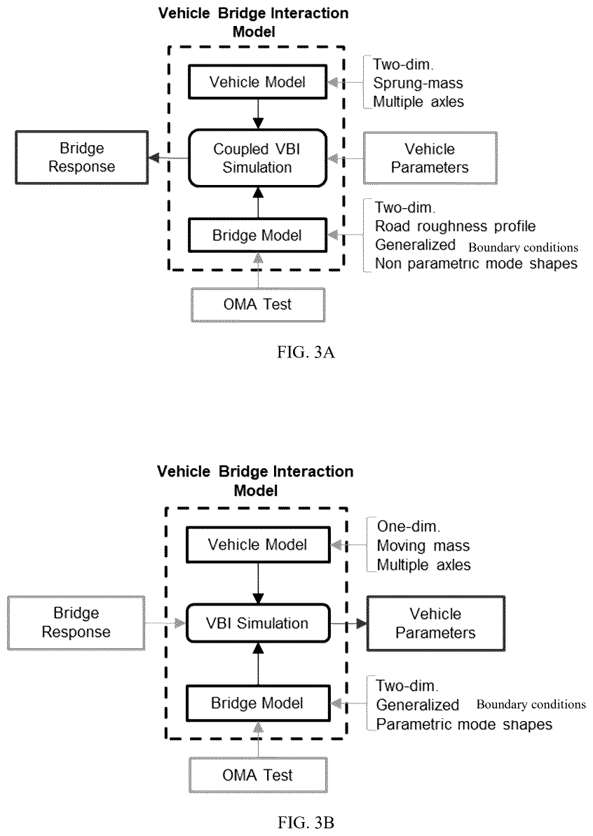

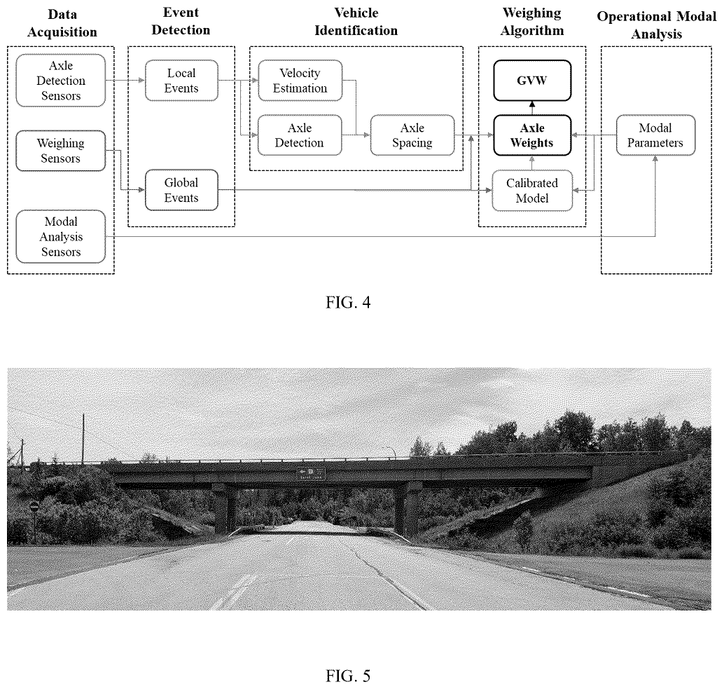

FIG. 1 B is a diagram that shows vehicle bridge interaction models with vehicle model parameters;

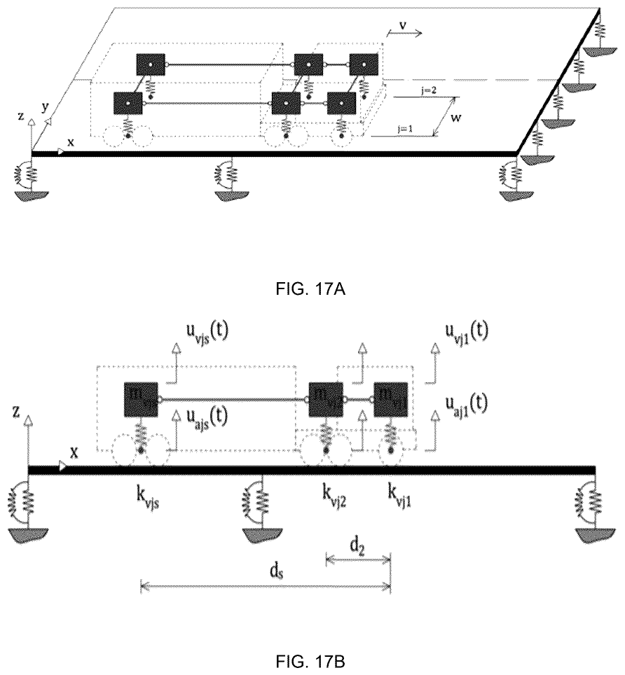

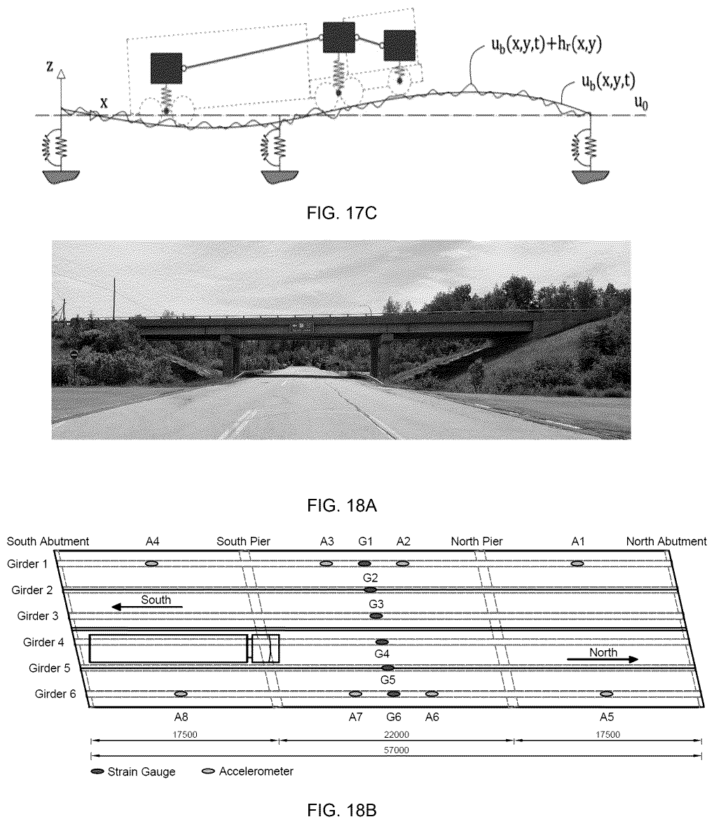

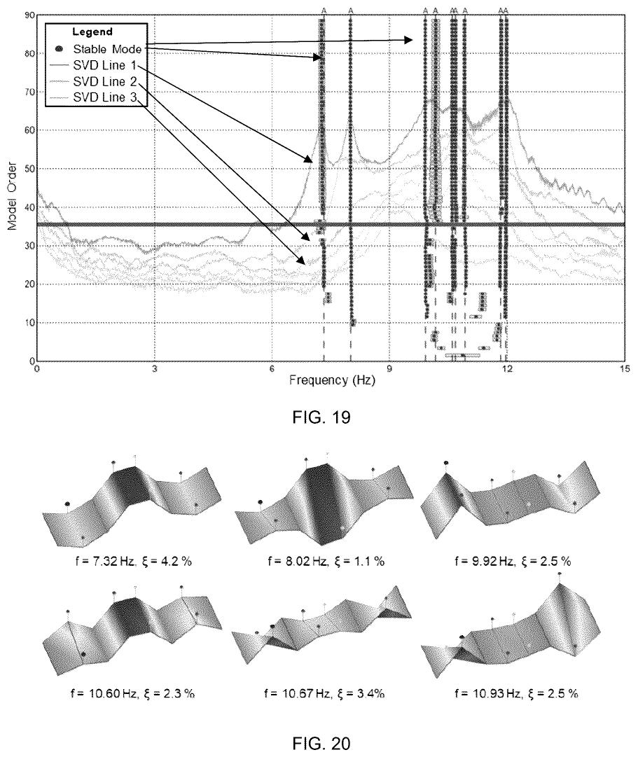

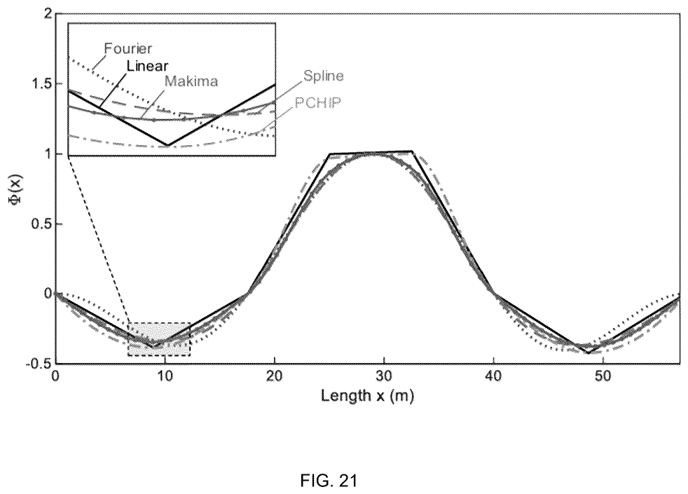

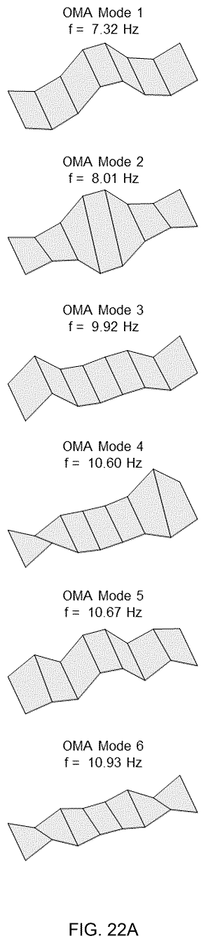

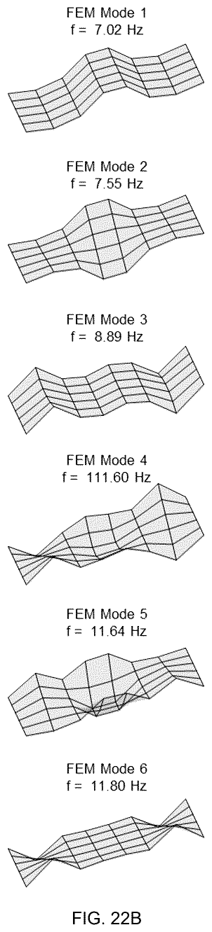

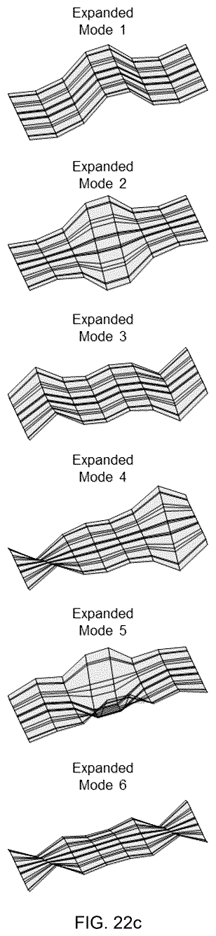

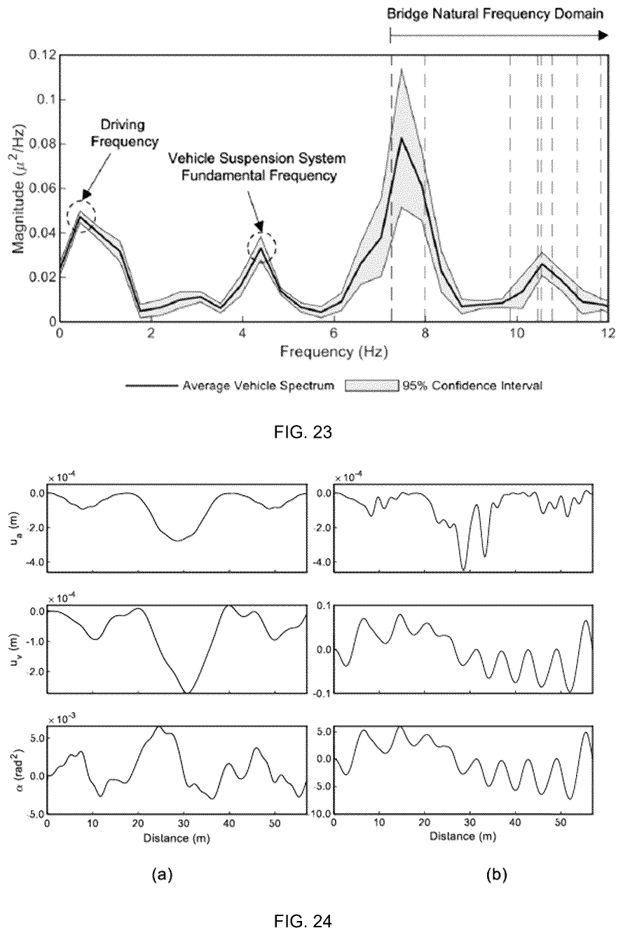

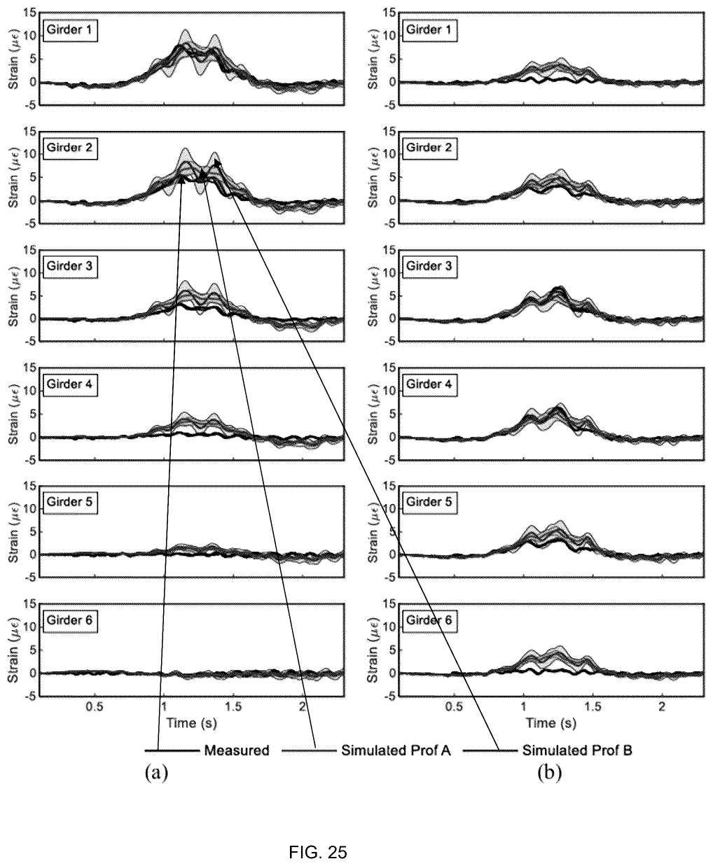

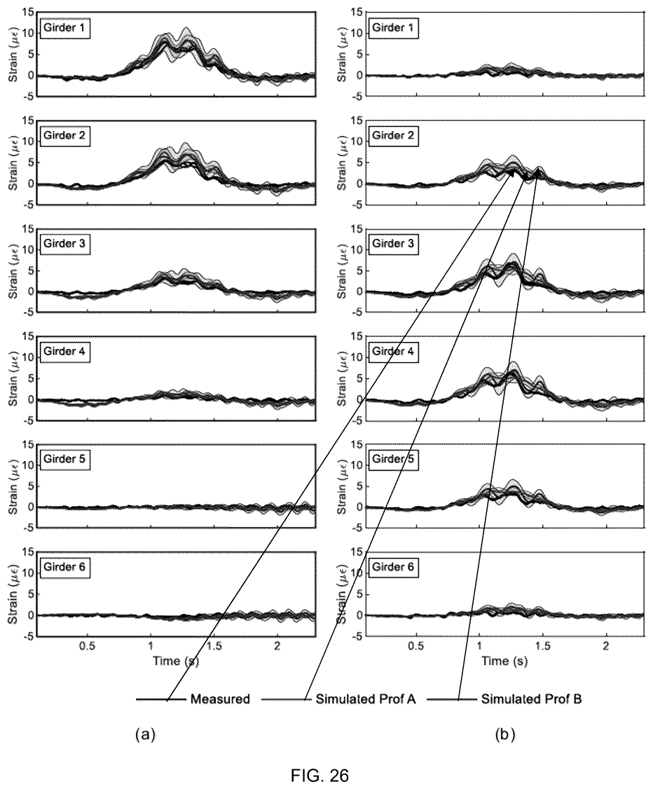

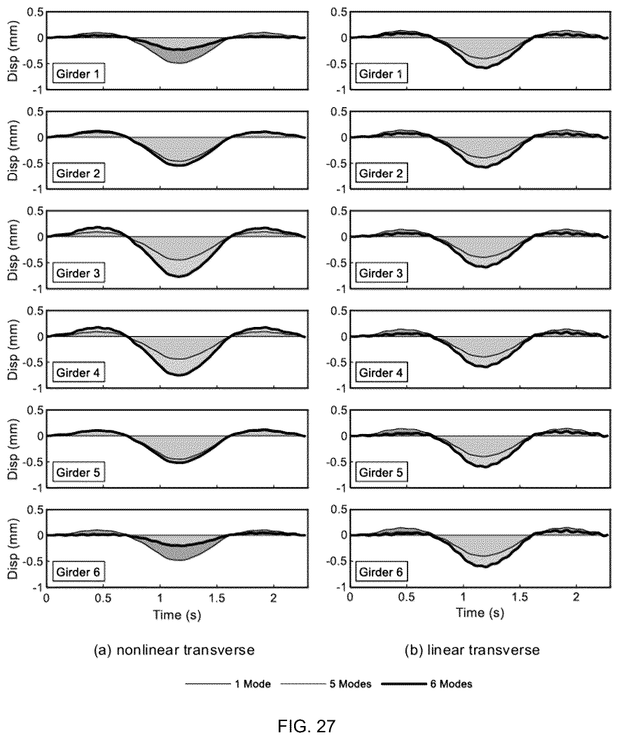

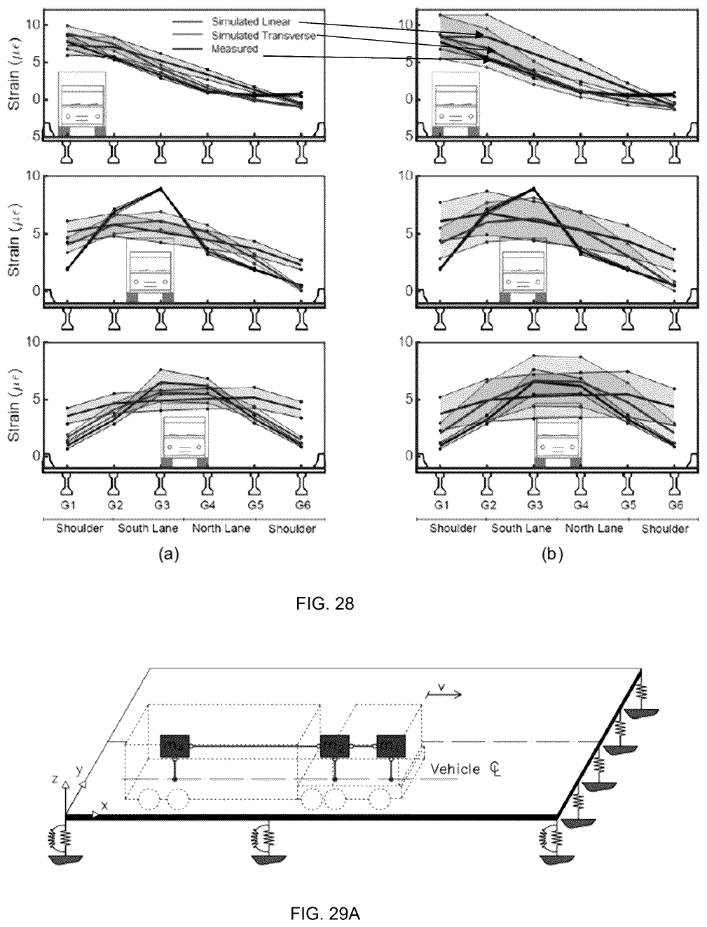

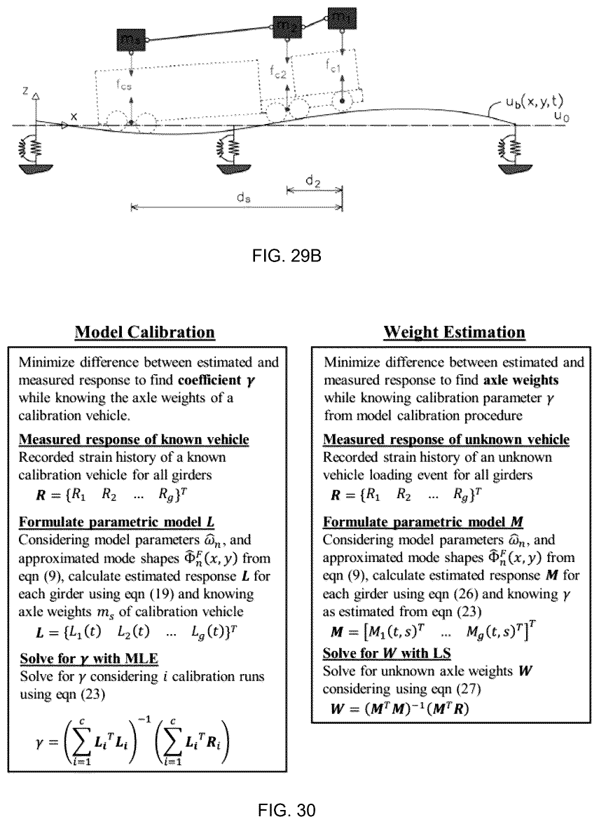

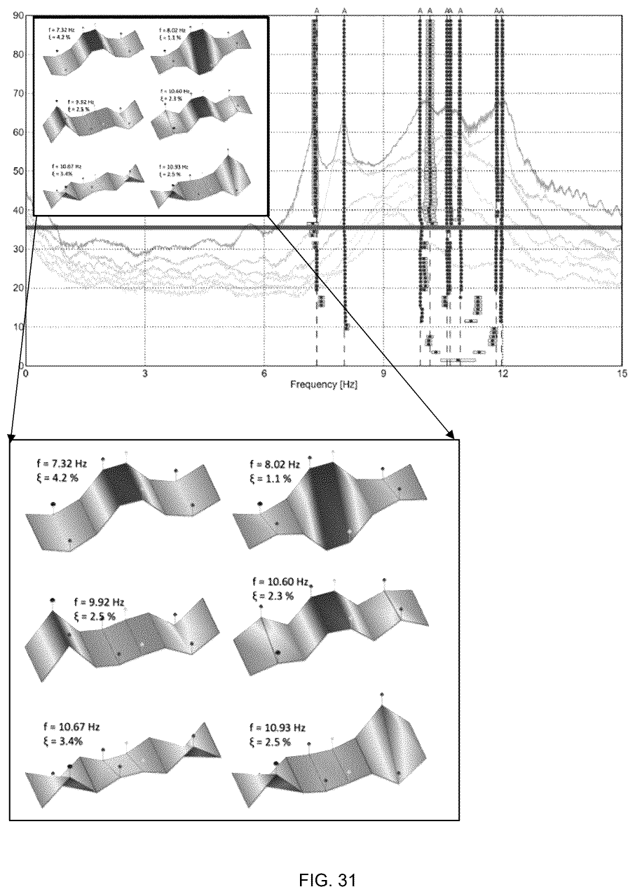

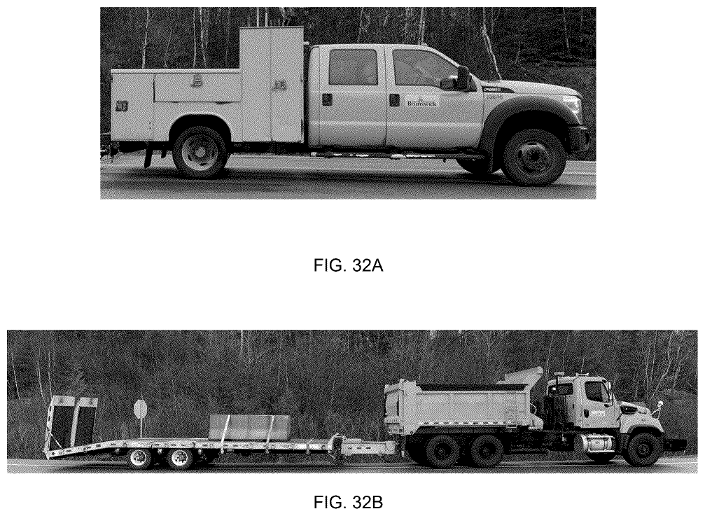

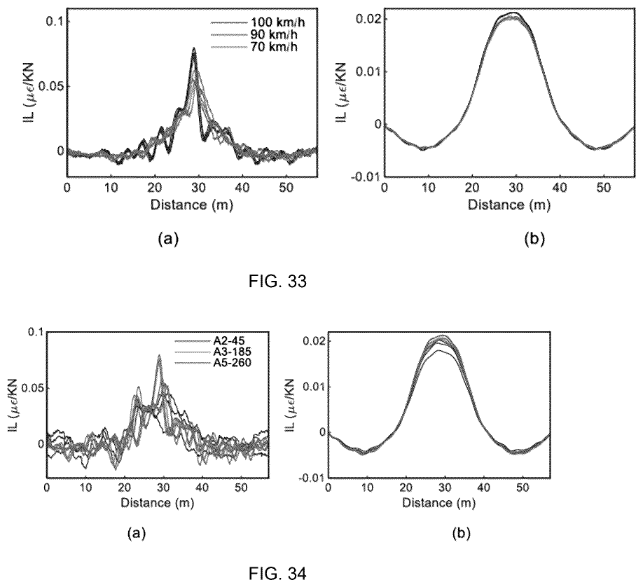

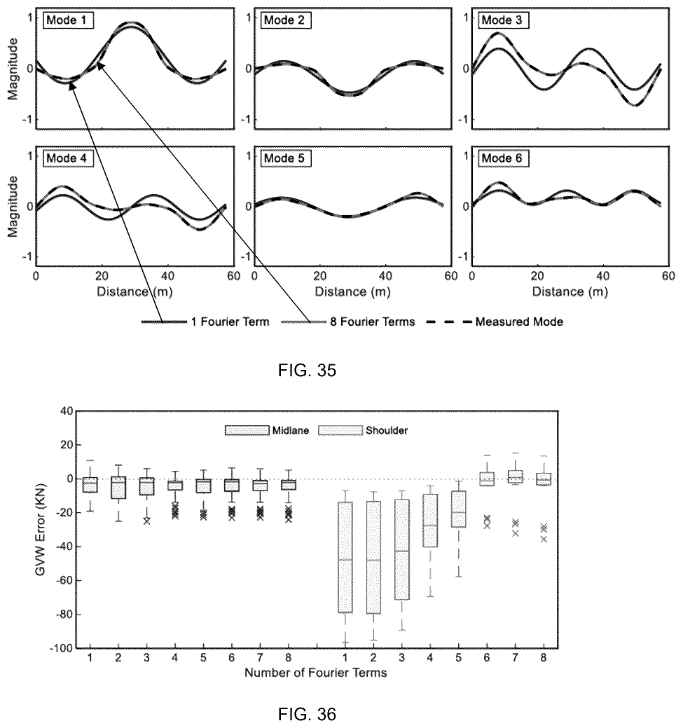

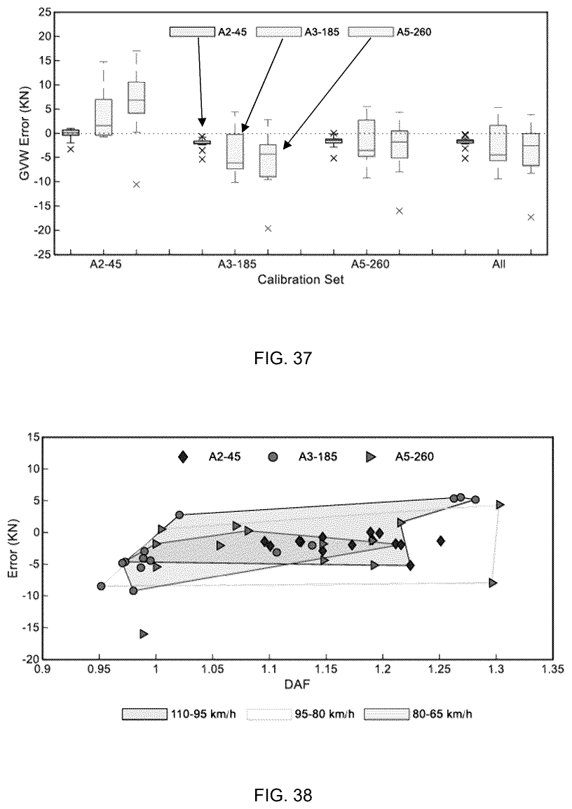

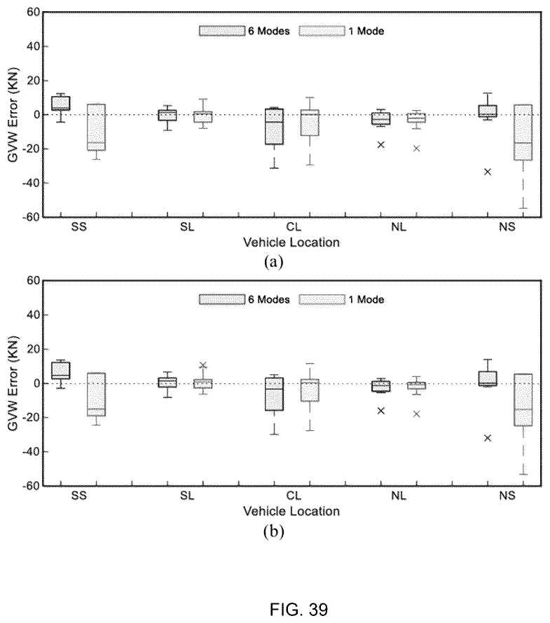

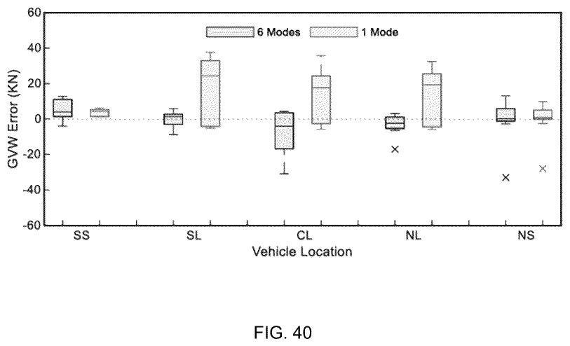

FIG. 17C is a diagram that shows vehicle bridge interaction models with bridge model parameters;

FIG. 18A is a photograph showing the elevation of Westfield Route 7 overpass (asset W475), the bridge chosen for the implementation;

FIG. 18B a diagram that shows the instrumentation of the bridge of FIG. 18A;

FIG. 19 is an SSI-UPCX Stabilization diagram;

FIG. 20 is diagrams of the first six estimated mode shapes, natural frequencies, and damping ratios;

FIG. 21 is a diagram showing interpolation results for 1^{st} mode of girder 1, using existing methods;

FIG. 22A contains diagrams showing OMA modes;

FIG. 22B contains diagrams showing paired FEM modes;

FIG. 22C contains diagrams showing expanded modes;

FIG. 23 is a graph showing strain spectrum for vehicle loading events;

FIG. 24 contains graphs showing the displacements of the bridge at the axle location, the wheel system, and differential acceleration term α for (a) profile N, and (b) profile A road surfaces;

FIG. 25 contains graphs that show simulated response using linear modes showing 95% confidence intervals for profiles A and B for a vehicle on the (a) shoulder, and (b) centerline of the bridge;

FIG. 26 contains graphs that show simulated response using nonlinear modes showing 95% confidence intervals for profiles A and B for a vehicle on the (a) shoulder, and (b) centerline of the bridge;

FIG. 27 contains graphs that show cumulative displacement for centerline load position for (a) linear, and (b) nonlinear transverse modes;

FIG. 28 contains graphs that show max mean girder strain and 95% confidence intervals for a vehicle travelling along the shoulder, mid-lane, and centerline for road profiles (a) A profile, and (b) B profile;

FIG. 29A is a diagram of a vehicle bridge interaction model showing a 3D arrangement;

FIG. 29B is a diagram of a vehicle bridge interaction model showing coupled system forces;

FIG. 30 is a summary of model calibration and weight estimation procedure;

FIG. 31 is a diagram of estimated mode shapes, natural frequencies. damping ratios and stabilization;

FIG. 32A is a photograph of a calibration vehicle, specifically a utility truck;

FIG. 32B is a photograph of a calibration vehicle, specifically a plow truck and trailer;

FIG. 33 contains graphs that show: a) Matrix Method IL, and b) Dynamic parametric influence line for girder 2, using A3-185;

FIG. 34 contains graphs that show: a) Matrix Method IL, and b) Dynamic parametric influence line for girder 2, extracted using all vehicle configurations at max velocity;

FIG. 35 is a diagram showing Fourier expansion of mode shapes evaluated at girder 2;

FIG. 36 is a graph that shows the effect of Fourier expansion on GVW results for mid-lane and shoulder positions;

FIG. 37 is a graph that shows GVW estimation for each vehicle considering different calibration data sets;

FIG. 38 is a graph that shows the effect of DAF on GVW error for the three vehicle configurations with shaded regions corresponding to the vehicle velocity;

FIG. 39 contains graphs that show GVW estimation for calibration using a) south lane, and b) north lane; and

FIG. 40 is a graph that shows GVW estimation for calibration using North Shoulder.

### DETAILED DESCRIPTION

Various apparatuses or processes will be described below to provide an example of an embodiment of each claimed invention. No embodiment described below limits any claimed invention and any claimed invention may cover processes or apparatuses that differ from those described below. The claimed inventions are not limited to apparatuses or processes having all of the features of any one apparatus or process described below or to features common to multiple or all of the apparatuses described below. It is possible that an apparatus or process described below is not an embodiment of any claimed invention. Any invention disclosed in an apparatus or process described below that is not claimed in this document may be the subject matter of another protective instrument, for example, a continuing patent application, and the applicants, inventors or owners do not intend to abandon, disclaim, or dedicate to the public any such invention by its disclosure in this document.

In the following sections, the following is described according to embodiments of the present invention: a system describing how to estimate vehicle parameters from acceleration; a vehicle bridge interaction model formulation and validation; and a parametric BWIM method formulation and validation.

### BWIM System Description

This section summarizes the instrumentation and design of a Dynamic BWIM and structural vibration monitoring system implemented at the Westfield Route 7 overpass (NBDTI asset W475) in Westfield, New Brunswick, Canada. It will cover the selection and preliminary analysis of the structure, instrumentation system design, installation, as well as programming and data management.

### Bridge Selection

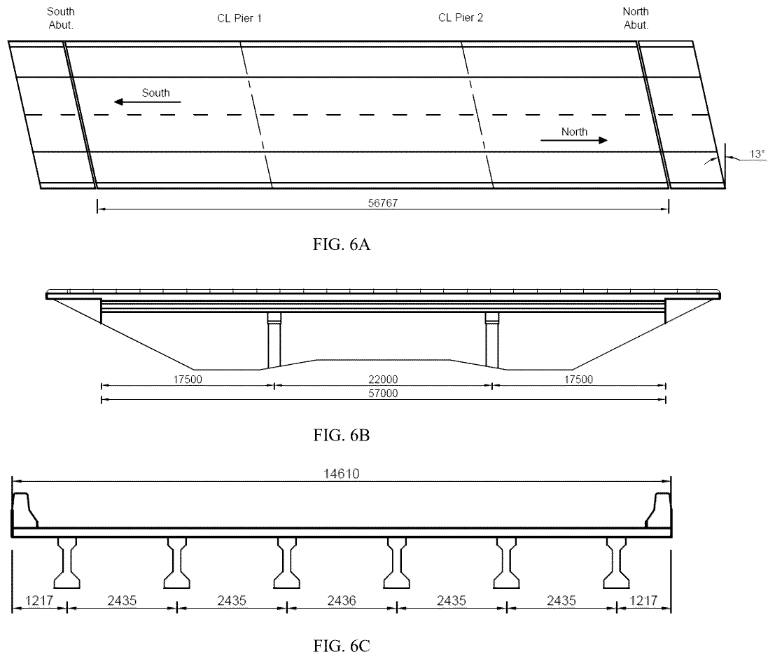

The structure chosen for instrumentation is the Westfield Route 7 overpass (W475). As shown in FIG. 5, the bridge is a 58 m three span bridge built in 1986 consisting of six continuous prestressed concrete girders. FIG. 6 shows the plan view (FIG. 6A), elevation view (FIG. 6B) and typical cross section (FIG. 6C) of the bridge. When selecting a structure to instrument, it is essential to consider the applicability to the implementation goals, suitability for analytical purposes, and feasibility of instrumentation. Considering the implementation goals, W475 was found to be a suitable candidate for achieving them. Route 7 is a heavy trucking route with mostly through traffic. This makes the selected bridge a good test structure for estimating the traffic characteristics of commercial vehicles passing between the cities of Saint John and Fredericton.

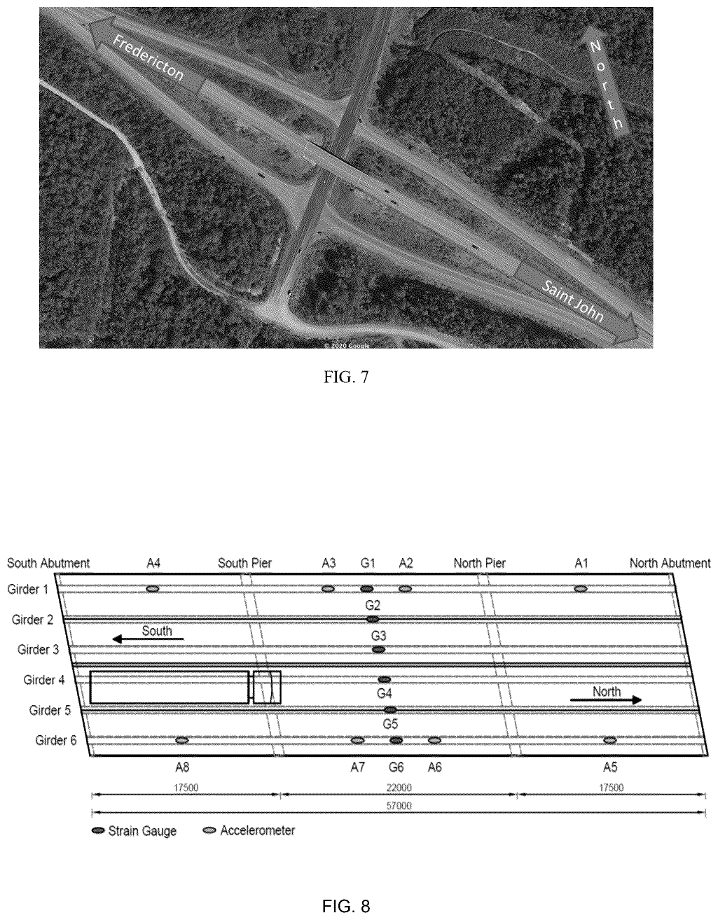

The second major consideration when selecting a structure to instrument is the suitability of the structure for the desired analysis. In order to increase the likelihood of completing successful modal identification from vibration monitoring it is necessary that the structure has suitable dynamic characteristics. In the case of W475, the structure does not possess any significant nonlinearities such as damage or large displacements, is relatively flexible due to its length, has symmetric span lengths and a relatively small skew of 13 degrees. When performing BWIM it is desirable for the vehicles to be travelling at a constant velocity across the bridge structure. The ramps for the Westfield overpass are located a considerable distance before and after the bridge, as shown in FIG. 7, allowing enough of an approach for traffic to reach a constant velocity while crossing the bridge. The bridge also has one lane in each travel direction. This eliminates the occurrence of side-by-side vehicles travelling in the same direction, which can greatly increase the complexity of analysis. The structure has some undesirable characteristics for BWIM such as a relatively long span, which can enable multiple vehicles to be present on the bridge simultaneously, adding complexity to the analysis.

The final consideration which can often be the limiting factor is the feasibility of instrumentation. There were a number of factors that contributed to selecting W475 as a feasible bridge to instrument. As it was not built over a waterway it was possible to install all instrumentation from below the structure using a ground-based lift. This enabled no disruption to the highway traffic on the bridge and only moderate disruption to the traffic below. Power can also be a limiting factor when designing a Structural Health Monitoring (SHM) system as often, due to the remote location of bridges, the only option is to use batteries or solar. Due to the power demands and reliability requirements of the monitoring system these were not a viable option. A physical power point was required which was already present at W475 from previous maintenance on the expansion joints.

As the SHM system must be able to communicate results in real-time it was necessary to determine that there was adequate cellular coverage at the site.

### Instrumentation Design

The monitoring system was designed to perform vibration monitoring as well as function as a traditional BWIM system. This combination of monitoring systems created the potential for hybrid monitoring opportunities. The system needed to be permanent and reliable and was designed to be modular to enable future hardware and software upgrades. The following section outlines the detailed considerations for the instrumentation design to achieve these goals.

### Sensor Location Selection

For BWIM systems, two types of sensors must be considered: axle detection sensors which measure the local response, and weighing sensors which measure the global response. In traditional BWIM systems, Free-of-Axle Detector (FAD) algorithms have been developed where sensors, typically strain gauges, are placed underneath the bridge and the vehicle properties can be extracted from the localized structural response (WAVE, 2001). Typically, two FAD sensors are allocated to each lane, where one of the sensors should be mounted at around 20%-40% of the span and the other at around 60%-80% of the span (Kalin et al., 2006). Based on the results of the experimental tests conducted by Brown (Brown, 2011), as shown in FIG. 8, the FAD sensors are located in the approach span to minimize the dynamic effects of the bridge and are installed on the underside of the deck at 33% of the span length. Having the sensors closer to the ends of the span improves the definition of the peaks due to increased local stiffness compared to midspan. The sensor orientation was selected to be transverse to the bridge longitudinal axis. Due to the one-way action of the slab, it was predicted this orientation should increase the width of the wheels path, enabling more reliable results when the vehicle deviates from the middle of the lane. Strain gauges were placed at midspan to measure the global bending strain response due to the vehicle loading as this will be the location of maximum bending strain. To avoid damaging the prestressing in the bottom flange, the gauges are placed in the web 150 mm above the chamfer of the bottom flange to avoid stress concentrations.

To determine the location and number of accelerometers necessary to capture the dominant mode shapes when performing Operational Modal Analysis (OMA), a simplified 3D beam model representative of the bridge structure was constructed in SAP2000. After performing analysis of the model, for each calculated mode shape the number of inflection points were identified. It was then possible to determine the required number of sensors to fully capture each mode shape as one sensor is required per inflection point. Based on these results it was decided to use 8 accelerometers to capture the first 6 mode shapes. Higher mode shapes can often be difficult to excite and contribute less to the overall structural response. It was therefore decided capturing higher modes did not justify the added cost of more sensors and channels. Accelerometers are installed along the underside of diaphragm beams in both the main and approach spans as seen in FIG. 8.

### Sensor Selection

Once the number of sensors and location has been established it is necessary to determine the specific sensor makes and models based on the required capabilities and operating conditions. The sensors selected for this implementation and the main specifications considered in their selection are summarized below in Table 1.

TABLE 1
Sensor types and model as well as the
key specifications for selection.

| Sensor Type | Model | Specifications |
|---|---|---|
| Strain Gauge | BDI ST350 | Strain Range of +/− 4000 με |
| | | IP67 rating |
| | | Temperature Rating: −50 |
| | | to +80° C. |
| Accelerometer | PCB 625B02 Uniaxial | Sensitivity (±5%) of 51 mV/m/ |
| | Low Frequency | Freq 0.2-2000 Hz ±5% tolerance |
| | Industrial ICP | Hermetic sealing and IP68 rating |
| | | Temperature Ranging −54° C. to |
| | | 121° C. |
| Camera | Basler acA1440-73gc | 73 frames per second |
| | with EO C Series 35 | 1.6 MP resolution |
| | mm Lens | Lab View compatible |

### Data Acquisition System Selection and Design.

The data acquisition system (DAQ) consists of two main components, a National Instruments (NI) CompactRIO (Real-time Industrial Controller), cRIO-9047 with a 1.60 GHz Quad-Core CPU, 4 GB RAM and 8 card slots as well as a Dell OptiPlex 7070 with Intel® Core™ i5-9500T (2.2 GHz) processor, 8 GB RAM and a 256 GB SSD. The cRIO-9047 is a rugged modular data acquisition system that runs a Linux Real-Time OS which results in very reliable long-term performance and determinism. The hardware enables the use of National Instruments LabVIEW programming language, which has many useful built-in functionalities for data acquisition applications. Though the cRIO-9047 can run headlessly once programmed, the Dell OptiPlex was added to the system to increase its capabilities and ease of access. Having a windows PC on site allows remote network access to monitor performance and deploy and debug new code modules. The PC also has greater internal expandable storage to store data locally, and the ability to communicate data to a database on a server. Finally, the PC enables some of the computationally expensive and non-time critical tasks to be unloaded from the cRIO to ensure the real-time system stays deterministic.

Once the data acquisition system is selected, a suitable enclosure must be sized and designed to meet the needs of the system. If the enclosure is accessible to the public, it should be locked and secure to avoid theft or vandalism and preferably placed out of direct line of sight from traffic or pedestrians. The enclosure selected for Westfield is a durable locking enamelled steel enclosure. It is anchored to the abutment between the girders and is therefore not readily visible from the roadway. As the enclosure needs to withstand the elements it is of weatherproof construction and has a vent and drain to reduce internal moisture and condensation. It is also important to consider the operating temperatures of the electronic hardware in the acquisition system. The cRIO-9047 is rated for a temperature range of −40° C. to 70° C., which is adequate; however, the Dell OptiPlex is only rated for 0° C. to 70° C. Therefore, a heater was added to the system to ensure the interior of the enclosure remains at 15° C. and ensure optimal performance. Fuses were included in the enclosure design to isolate each component from both the external power source and internal power supplies to protect sensitive equipment from surges or shorts.

### System Installation

When mounting the sensors, considerations were given to durability, the ease of installation from the lift, if special tools or hardware were required, how the mounting method would affect the quality of the signal, and finally, if the mounting method could inflict damage to the concrete structure. Many SHM systems in the literature are designed for short- to medium-term duration and therefore do not need to be installed with durable or protected hardware. The goal of this implementation was to be permanent and in place for multiple years, therefore a lot of attention was spent developing a system that would be secure and durable. Often in short term applications, bare cables can be taped or strapped to the structure being monitored. Instead, to improve weather resistance, the entire system at Westfield is enclosed in PVC flexible and rigid schedule 40 conduit. The conduit was installed in the web just above the chamfer to provide a flat surface for clamping. Anchors and brackets were used that did not fully penetrate the cover and risk damaging reinforcement. Custom drilled PVC junction boxes with rigid and liquid tight fittings were used at the conduct intersections and sensor locations for ease of installation and maintenance.

The rigid conduit and junction boxes were installed first to ensure proper fit and avoid damaging the sensors and cables. A pull string was installed in the conduit to allow the cables to be pulled through as the sensors were installed afterwards. This was done beginning furthest from the DAQ and working back towards it. To facilitate the cable pulling, a low conduit utilization was used and the cables were bundled together and pulled as one unit to reduce friction and winding. One aspect that proved more difficult than expected was pulling the cables through the conduit. The long runs and sharp 90-degree bends can add significant friction to the point it was no longer possible to make any progress. Lubricating the cables with a wire lubricant solved this problem and enabled the installation to be completed without damaging the cables.

The strain gauges were mounted with 600 mm gauge extensions, with the weighing sensors in the web and the FAD sensor below the deck. The gauge extensions were used to ensure average strain in the concrete and not aggregate strain was being measured based on manufacturer recommendations for sensor use with concrete. The gauges were mounted following the manufacturers recommendation of using 0.25-inch diameter HILTI KBV anchor studs that were drilled 30 mm into the concrete to stay in the concrete cover. All of the studs, nuts and washers are stainless steel to avoid corrosion.

The accelerometers were mounted to the bridge under the diaphragm with a custom threaded stainless-steel rod secured into a seismic drop-in anchor. The custom fabricated rod was necessary to interface between the ⅜″-16 thread of the anchor and the internal ¼″-28 thread of the accelerometer. The middle portion of the shaft was unthreaded to ensure that the accelerometer was “free floating” and clamped to the bridge with the top nut, rather than threaded to the rod itself. This is to eliminate the natural frequency of the rod from the measured spectrum. The anchor was selected for its shallow embedment depth which is less than the thickness of cover and its performance in cracked concrete. A spherical washer assembly was used between the sensor and concrete to account for any out of plumbness of the hole and ensure an even contact interface. All hardware used is stainless steel to reduce corrosion.

The DAQ enclosure is mounted on the abutment on two sections of square channeling with the power and camera cable entering from the side and the data cables entering from the bottom. The separation of power and sensor cables is to reduce the chance of electrical noise in the measured signal. The camera was mounted to the existing power pole in a weatherproof with the cables run in a flexible conduit buried in the embankment.

### Programming and Data Management

Data processing and acquisition is performed using LabVIEW, the native programing language for National Instruments. This enables seamless integration with the cRIO system and many useful toolboxes and functionalities. LabVIEW is a visual programing language composed of subroutines called a Virtual Instrument (VI). For this implementation, two main VIs were designed, one to collect the acceleration and strain sensor data from the cRIO modules while the other captures images from the camera. Both VIs follow similar architecture and consist of an initialization phase followed by a data acquisition loop.

As the cRIO has a Linux Real-Time operating system, it can be programmed to run independent of the host mini-computer to ensure reliable data collection that is not reliant on a stable network connection between the two devices. Linux Real-Time is a deterministic OS that is designed to run applications with very precise timing and a high degree of reliability. It does this by providing a high degree of control over how tasks are prioritized. This is useful to ensure that data collection is prioritized over background tasks so no data loss occurs and no loading events are missed. Real-time operating systems typically run a minimal set of software rather than many applications and processes at the same time. This results in increased reliability for systems that must run continuously for long durations of time. Adding to the long-term reliability of the system, in the event of a loss of power, upon the return of power, both the CRIO and the mini-computer are programmed to restart, and the cRIO will initialize and execute the VIs automatically without intervention ensuring minimal disruption to data collection.

The first portion of the code creates a data acquisition task and defines a channel type. This is where the various sensor parameters are defined for each individual sensor. Once the sensors are initialized, the sampling parameters are defined such as the sample rate and buffer size. The cRIO reads the collected data from the buffer at each iteration of the data acquisition loop, therefore a large enough buffer must be defined so the code has time to read and execute without a backlog of data occurring. While the sensor and channels are being initialized, the data file and path is concurrently created. The file name is time stamped for clear organization and the length of the recording time of each file is defined in seconds. The recording length is set to one hour to keep individual file sizes from becoming too large and to facilitate data processing. The sensor parameters were selected based on the manufacturer recommendations, environmental conditions, and analysis requirements.

The data acquisition portion of the code occurs in a while loop. The data is read from the buffer at each iteration and is displayed to the user and saved to file. To determine when a new file should be created, first the code checks the current time against the target time based on the defined file duration. If the time has not been reached, the code continues to write to the current file. If the time has been reached, the current file is closed, and a new time stamped file is created. The data acquisition loops for each sensor type wait 50 ms after each iteration to ensure resources are shared between the loops.

The acceleration and strain data are stored in separate TDMS format (Technical Data Management Streaming) files that also include the sensor parameters and sampling information. The TDMS file format is a binary file format developed by National Instruments that is an easily exchangeable, inherently structured, high-speed-streaming capable file format. The image files were initially saved as JPEG (Joint Photographic Experts Group) files to reduce the file size. The combined system produces approximately 20 GB of data a day. The cRIO saves the data to a local 3 TB external hard drive which provides storage for approximately 160 days in the event that network file transfers are unavailable.

Extraction of Vehicle Parameters from Sensor Data

In this implementation, a novel acceleration-based vehicle identification method is introduced and implemented in a hybrid strain-acceleration based BWIM system, resulting in improved accuracy. The new BWIM system uses accelerometer sensors for axle identification and strain gauge sensors for the measurement of global bridge deformations. The implementation of such a system was validated through a full-scale implementation on an arterial highway bridge in the Province of New Brunswick in Canada. The validation includes 104 events of four vehicle types, where the effect of travel direction, transverse position, vehicle velocity and vehicle configuration were captured in detail. A systematic evaluation of existing methods for velocity estimation and axle detection was conducted. The inventors also evaluated the effect of improved axle identification accuracy using the proposed system on the GVW estimation. From this implementation, it was found that the proposed hybrid system resulted in a BWIM system with improved accuracy in comparison to FAD based systems.

### Proposed Acceleration Based Vehicle Identification

In the hybrid BWIM system, acceleration data is used for vehicle identification. The concept of the method will be illustrated through the data from the Westfield Bridge implementation. Although the methodology presented here can generally be applied to other bridges, some of the parameters used are required to be calibrated for the structure of interest.

### Velocity Estimation

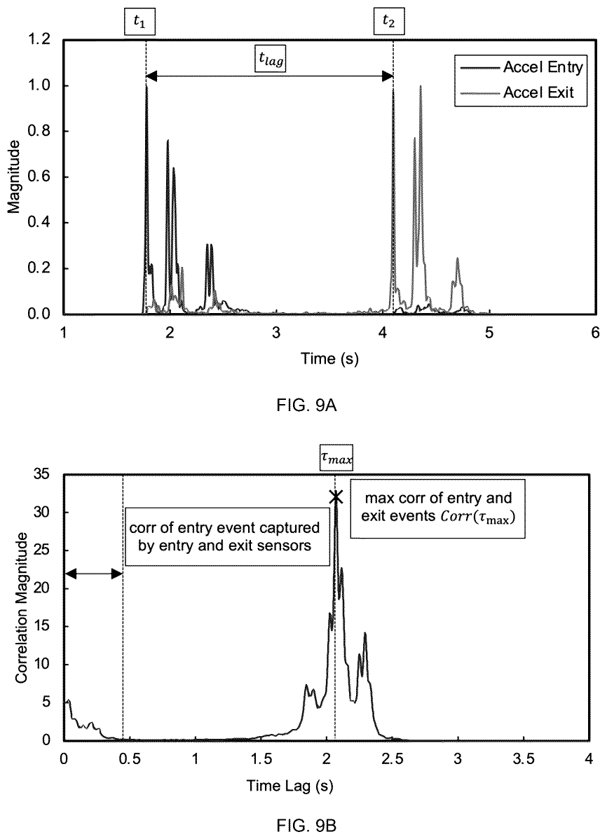

It was found that acceleration data collected from the entrance and exit accelerometer sensors can be used for accurate measurement of vehicle velocity using correlation methods. The correlation approach is an alternative method to the peak-to-peak detection method. This method calculates the correlation between two time-shifted signals from different sensors using equation (1):

$$Corr ( {a}_{exit} , {a}_{entry} ) ( t ) = {\int }_{0}^{{t}_{end}} {a}_{exit} ( τ ) {a}_{entry} , ( t + τ ) d τ \qquad ( 1 )$$

Where aₑₓᵢₜ and a_{entry} are the signal collected from the exit and entry sensors respectively and t_{end} is the duration of the event. The position of the maximum peak in the correlation function determines the time-shift between signals which is used to find the vehicle speed. In FIG. 9b, the maximum peak in the correlation function between accelerometers for a 3-axle vehicle occurs at a time lag τ of 2.071 s. Using the distance between expansion joints of 57.57 m results in a velocity of 100.1 km/h. Since the exit sensor is also sensitive to the vehicle entrance as seen in FIG. 9A, the correlation method captures a relatively small correlated region in the vicinity of zero time lag (τ=0) as shown in FIG. 9B.

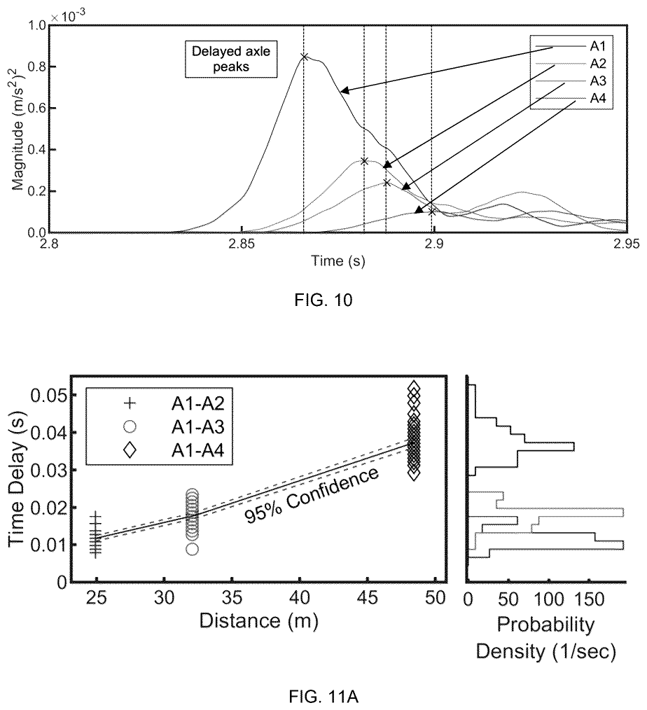

As the accelerometers are detecting the impact of the wheels hitting the expansion joints, there is a lag in the signal between when the impact occurs and when the impact is detected by the sensors along the girder. This is due to the transmission speed of the wave propagating through the bridge. This delay between impact peaks can be seen in FIG. 10 which shows the peak acceleration measured in sensors A1 to A4 corresponding to the first axle impacting the expansion joint.

The time lag was further investigated by analyzing the 104 calibration runs used in this implementation, which are described in detail in the following sections. The runs were divided by direction and the cumulative time lags between the first axle peaks were calculated, i.e. between sensors A1-A2, A1-A3, and A1-A4 as well as A8-A7, A8-A6, and A8-A5, for the southbound (FIG. 11a) and northbound (FIG. 11b) lanes respectively. The calculated cumulative time lags are plotted against the distance between the sensors, along with the 95% confidence interval and the probability density of each sensor's lag. Considering the lags' narrow probability distribution and confidence intervals it was determined that consistent estimation of the lags was possible and that they were the same for both travel directions. It can be seen that the cumulative lags, when plotted against distance, are relatively linear, indicating the impact wave is traveling at a near-constant speed through the bridge. Due to these characteristics, it was possible to calculate the average speed of the wave and extrapolate that the time delay from when the vehicle strikes the expansion joint to when the peak is recorded in the approach span accelerometer is approximately 0.007 seconds. For this bridge structure the time delay was deemed negligible; however, if a longer span is considered or a different sensor layout is used then these effects may be more significant.

### Axle Detection

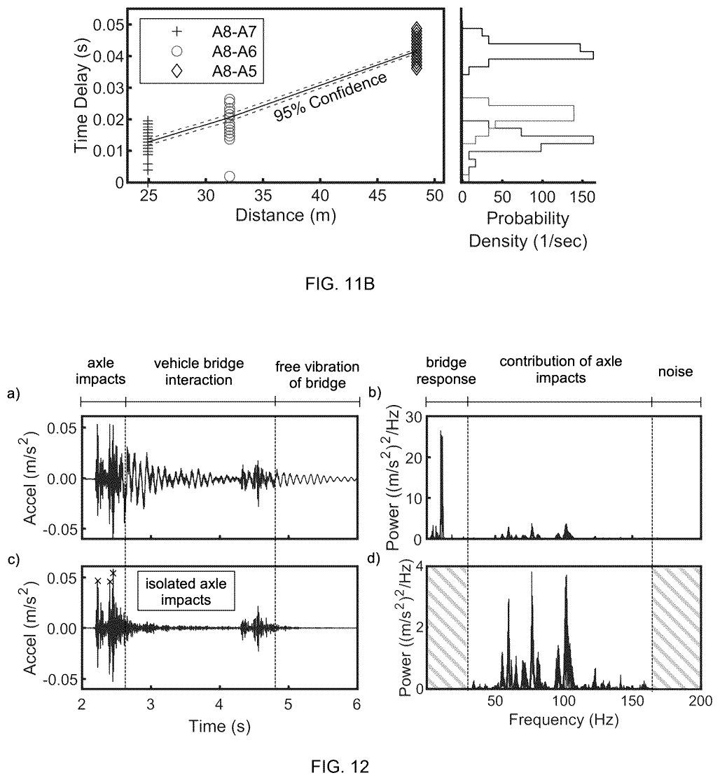

As a vehicle enters the bridge, the acceleration data collected from discrete points on the primary bridge girders exhibit contributions of both the bridge and the vehicle axles. This is clear in the sample data for a 3-axle vehicle event shown in FIG. 12a. As seen in this figure, the event starts with sharp peaks in an impact zone as the result of the contact of tires and the expansion joints. This is followed by the vehicle-bridge interaction period where the coupled vehicle-bridge system is subjected to forced vibration. In the last phase, the bridge experiences a free vibration zone after the vehicle exits the bridge.

As seen in FIG. 12b, the frequency spectrum of an event can be calculated using the direct Fourier transform. In this implementation, it was observed that the spectrum contains three frequency zones. The low frequency range is dominated by the energy from the bridge free vibration and the coupled bridge-vehicle system forced vibration. The high frequency range is associated with higher vibration mode contributions and the ambient and system noises. It was found that the mid-range frequency is associated with vehicle tire impacts at the expansion joints. FIG. 12c and FIG. 12d illustrate the acceleration signal after applying a band pass filter to remove the low and high frequency zones.

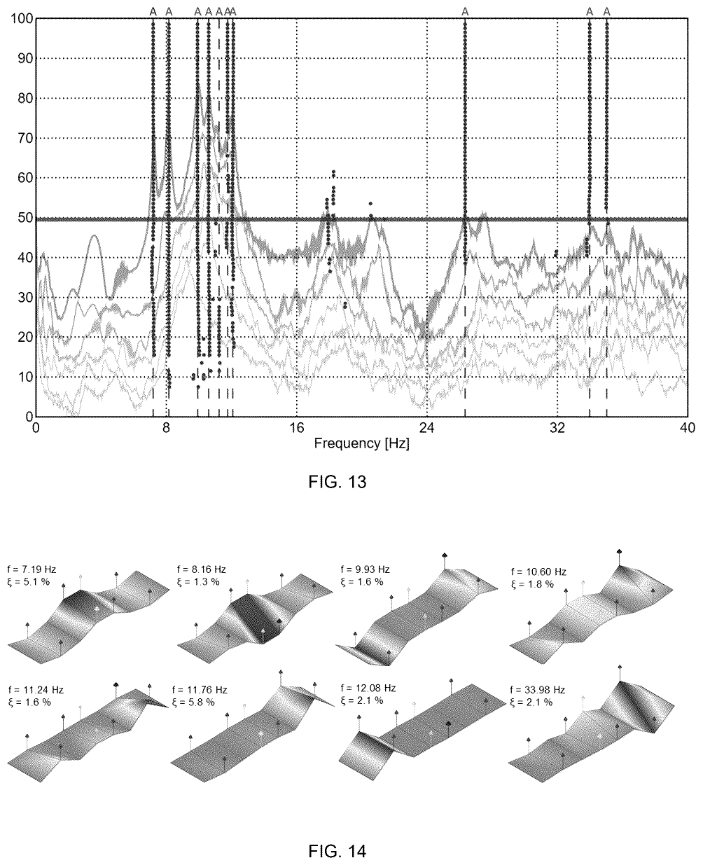

To determine the boundary of the bridge response the modal parameters of the bridge structure were estimated using the Stochastic Subspace Identification Unweighted Principal Component (SSI-UPC) OMA method with ARTeMIS Modal software. The stabilization diagram and the first eight estimated mode shapes, frequencies and damping ratios are shown in FIG. 13 and FIG. 14, respectively. As evident by the stabilization diagram, the dominant structural modes have frequencies of below 35 Hz. Above a frequency of 160 Hz, the acceleration signal contains minimal contribution from the loading event. Therefore, for this implementation, a bandpass filter of 35 Hz to 160 Hz successfully isolated contributions from the axles impacting the expansion joints resulting in clear axle peaks in FIG. 12c.

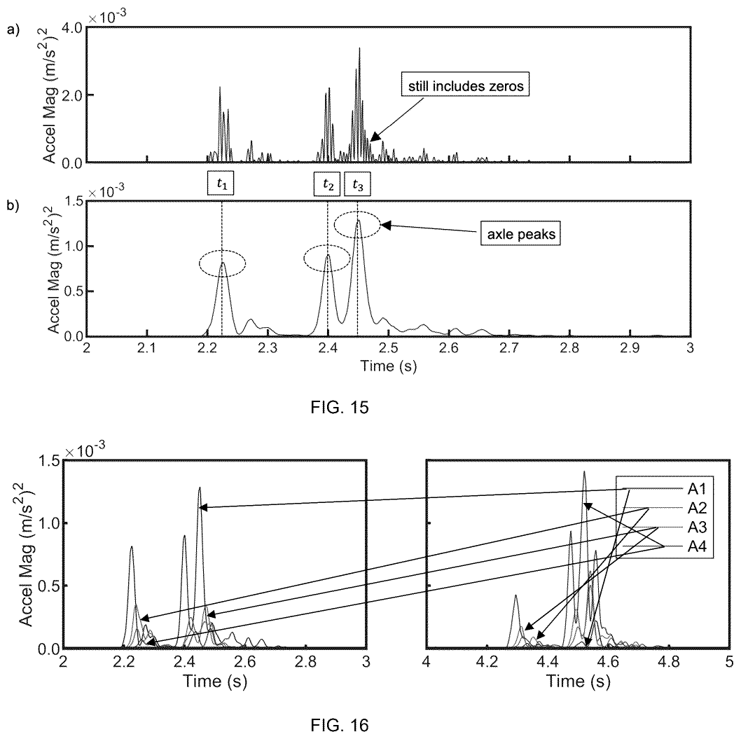

To make the peaks more prominent, after transforming the band-passed filtered signal to the time domain, first, the time domain signal was squared to promote peaks and ensure the signal is positive to facilitate peak picking. Since the zero crossings are still present in the signal as seen in FIG. 15a, it was smoothed by applying a double moving average filter with a window size of 15 data points. The result for the same signal from FIG. 12 is shown in FIG. 15b where three, well-defined peaks can be seen corresponding to the axle impacts.

Once the filtering is complete, peak picking is used to determine the number of axles, and the time lag between axles. In this implementation, a minimum peak prominence for selection was defined as 2.5 times the signal rms to account for changing noise conditions and a minimum peak distance was defined as 0.5 m which is the smallest expected axle spacing. The time lag, along with the estimated velocity, is used to determine the axle spacing of the vehicle. It is recommended to utilize the specific BWIM instrument RMS values to calibrate the peak, picking parameters for each bridge project and to avoid the use of a nominal threshold.

To determine the optimal sensors to use for axle identification, the quality of the signals from different locations was compared for vehicle crossing events. For each direction of travel, the accelerometers closest to the travel lane were considered, i.e. sensors A1, A2, A3, and A4 for southbound traffic and sensors A8, A7, A6, and A5 for northbound traffic. Considering a southbound 3-axle vehicle event, the segments of the signal corresponding to the vehicle entry and exit are shown in FIG. 16a and FIG. 16b, respectively, with the horizontal axis showing the time within the event. It is clear that the sensors located further away from the expansion joints become significantly less sensitive to both the entry and exit events. Therefore, it was determined that the sensors located in the approach spans give the best signals for vehicle entry and exit. Considering the application of the signals for axle detection it can be seen that the entry signal has cleaner and more pronounced peaks corresponding to the axle impacts.

### Vehicle-Bridge Interaction Model

List of Symbols

| | |
|---|---|
| ∇⁴ | Biharmonic operator |
| a | Plate length |
| b | Plate width |
| D | Plate flexural rigidity |
| dₛ | Distance between the s^{th} and first axle |
| f_{cjs} | Wheel system contact force |
| g | Number of girders |
| g | Acceleration due to gravity |
| h | Plate thickness |
| hᵣ | Road roughness profile |
| j | Wheel row |
| kᵥⱼₛ | Equivalent concentrated stiffness at each vehicle degree |
| | of freedom |
| m̅ | Plate mass per unit length |
| mᵥⱼₛ | Equivalent concentrated mass at each vehicle degree of freedom |
| na | Total number of axles |
| pⱼₛ | Vehicle wheel system applied force |
| q_{bn} | Bridge response in modal coordinates |
| s | Axle number |
| û_{b} | Estimated vertical displacement of the bridge |
| uₐⱼₛ | Displacement associated with the contact point of wheel system |
| u_{b} | Vertical displacement of the bridge |
| uᵥⱼₛ | Vertical displacement of vehicle wheel system |
| v | Axle speed |
| w | Wheel row spacing |
| δ | Dirac delta function |
| δⱼₛ | Differential displacement between the vehicle wheel system |
| | and the bridge |
| ε | Bending strain |
| ρ | Plate mass per unit areas |
| \hat{Φ}ₙ | Extracted mode shapes of the bridge |
| Φₙ | Normal mode shapes |
| \hat{ω}ₙ | Extracted natural frequencies of the bridge |
| ωₙ | Plate natural frequency |
| ωᵥⱼₛ | Vibration frequency of the vehicle wheel system |

This section outlines the derivation of the vehicle-bridge coupled dynamic formulation accounting for bridge three-dimensional behaviour, bridge surface irregularities, and vehicle moving sprung mass system. The bridge surface is considered as an elastic generalized plate subject to a series of vehicle axles moving at speed v as shown in FIG. 17A. The plate is assumed to follow classical plate theory and to have a constant cross-section with length a, width b, thickness h, mass per unit areas ρ, and flexural rigidity D. The effects of bridge damping are neglected and the support conditions and the number of bridge spans are arbitrary.

A multi-axle vehicle model is considered. Vehicle axles are represented as two concentrated sprung masses at a constant spacing (w) between wheel rows j=1 and j=2. FIG. 17B shows dₛ is the distance between the s^{th} and first axle (d₁=0) with na being the total number of axles; mᵥⱼₛ and kᵥⱼₛ are the equivalent concentrated mass and stiffness at each vehicle degree of freedom. The damping of the vehicle suspension system is neglected.

Beginning with the classical equation of motion of a plate (Rao, 2006a), the coupled equations of motion governing the vibration of the bridge and vehicle system can be expressed as:

$$\overline{m} \frac{{\partial }^{2} {u}_{b} ( x , y , t )}{\partial {t}^{2}} + D ∇ {u}_{b} ( x , y , t ) = {\sum }_{j = 1}^{2} {\sum }_{s = 1}^{na} {p}_{js} ( x , y , t ) \qquad ( 2 )$$

$${{m}_{vjs} \frac{{d}^{2} {u}_{vjs} ( t )}{{dt}^{2}} + {k}_{vjs} {u}_{vjs} ( t ) = {k}_{vjs} {u}_{ajs} ( t ) \vert}_{x = vt - {d}_{s} , y = {y}_{js}} \qquad ( 3 )$$

where u_{b}(x,y,t) is the vertical displacement of the bridge (FIG. 17c), and pⱼₛ(x,y,t) is the applied force acting on the bridge through the contact point of the js^{th} vehicle wheel system at location x=vt−dₛ, and y=yⱼₛ measured from the bridge coordinate reference and m̅=ρh. The term ∇⁴ represents the biharmonic operator such that:

$${∇}^{4} {u}_{b} ( x , y , t ) = \frac{{\partial }^{4} {u}_{b} ( x , y , t )}{\partial {x}^{4}} + 2 \frac{{\partial }^{4} {u}_{b} ( x , y , t )}{\partial {x}^{2} \partial {y}^{2}} + \frac{{\partial }^{4} {u}_{b} ( x , y , t )}{\partial {y}^{4}} \qquad ( 4 )$$

The force pⱼₛ(x,y,t) can be expressed as:

$${p}_{js} ( x , y , t ) = {f}_{cjs} ( t ) δ ( x - vt + {d}_{s} , y - {y}_{js} ) \qquad ( 5 )$$

where δ(x−vt+dₛ, y−yⱼₛ) is a two-dimensional spatial Dirac delta function defined by:

$$\{ \begin{matrix}δ ( x - {x}_{0} , y - {y}_{0} ) = 0 for x \neq {x}_{y} \vert y \neq {y}_{0} \\ {\int }_{0}^{a} {\int }_{0}^{b} δ ( x - {x}_{0} , y - {y}_{0} ) dxdy = 1\end{matrix} \qquad ( 6 )$$

The contact force f_{cjs} is the sum of the axle weight and the suspension system elastic force at the vehicle tires:

$${{f}_{cjs} = - {m}_{vjs} g + {k}_{vjs} ( {u}_{vjs} ( t ) - {u}_{ajs} ( t ) \vert}_{x = vt - {d}_{s} , y = {yj}_{s}} ) \qquad ( 7 )$$

where uₐⱼₛ(t)=u_{b}(x,y,t)+hᵣ(vt−dₛ, yⱼₛ) is the displacement associated with the contact point of the js^{th} wheel accounting for the deviation in bridge profile due to road roughness hᵣ shown in FIG. 17C, g is the acceleration due to gravity and uᵥⱼₛ is the vertical displacement of the js^{th} vehicle wheel system. uᵥⱼₛ can be evaluated using the equation of motion of the vehicle system in eqn. (3). The solution to equation (2) can be expressed in terms of a linear combination of the normal mode shapes Φₙ(x,y) and associated modal coordinates q_{bn}(t) as:

$${u}_{b} ( x , y , t ) = {\sum }_{n} {Φ}_{n} ( x , y ) {q}_{bn} ( t ) n = 1 , 2 , … n \qquad ( 8 )$$

where the mode shapes are traditionally found by solving the eqn. (9) using the boundary conditions of the plate:

$${∇}^{4} {Φ}_{n} ( x , y ) - {λ}_{n}^{4} {Φ}_{n} ( x , y ) = 0 \qquad ( 9 )$$

where,

$${λ}_{n}^{4} = \frac{\overline{mD} {ω}_{bn}^{2}}{} \qquad ( 10 )$$

and ω_{bn} is the bridge natural frequency:

$${ω}_{bn} = {λ}_{n}^{2} \sqrt{\frac{D}{\overline{m}}} \qquad ( 11 )$$

The closed form solution for the mode shapes consists of multiple terms of trigonometric and hyperbolic functions where constants are solved considering the boundary conditions, and they must be evaluated for each span. In the case of simple beams, closed-form solutions can be found in classical references (Rao, 2006b). For multiple span plate structures and complex boundary conditions, the modal parameters can be extremely cumbersome to evaluate in a closed-form solution. Further, detailed information must be assumed about the flexibility, material properties and in-situ boundary conditions of the structure which is not always practical or accurate. Therefore, in this implementation, a formulation is developed that directly employs the extracted mode shapes \hat{Φ}ₙ(x,y) and natural frequencies \hat{ω}ₙ of the bridge using the operational modal testing of a bridge instead. This enables the response of the bridge to be calculated without the calculation of modal parameters in eqn (9). In the following equations the “\hat{ }” denotes estimated values from the bridge modal testing. Using the in-situ estimated mode shapes, allows the proposed solution to account for the bridge geometry, material properties, composite actions, connection effects and boundary conditions. Considering the estimated modal parameters, eqn. (8) can be rewritten as:

$${\hat{u}}_{b} ( x , y , t ) = {\sum }_{n} {\hat{Φ}}_{n} ( x , y ) {q}_{bn} ( t ) \qquad ( 12 )$$

Substituting eqn. (12) for the displacement of the bridge into (2) yields:

$$\overline{m} {\sum }_{n} {\hat{Φ}}_{n} ( x , y ) \frac{{d}^{2} {q}_{bn} ( t )}{{dt}^{2}} + D {\sum }_{n} {∇}^{4} {Φ}_{mn} ( x , y ) {q}_{bn} ( t ) = {f}_{cjs} ( t ) δ ( x - vt + {d}_{s} , y - {y}_{sj} ) \qquad ( 13 )$$

Using eqn. (9), eqn. (13) can be rewritten as:

$$\overline{m} {\sum }_{n} {\hat{Φ}}_{n} ( x , y ) \frac{{d}^{2} {q}_{bn} ( t )}{{dt}^{2}} + \overline{m} {\sum }_{n} {\hat{ω}}_{bn}^{2} {\hat{Φ}}_{n} ( x , y ) {q}_{bn} ( t ) = {f}_{cjs} ( t ) δ ( x - vt + {d}_{s} , y - {y}_{js} ) \qquad ( 14 )$$

Pre-multiplying both sides by \hat{Φ}ₘ(x,y) and integrating over the bridge area results in eqn. (15) which only include terms where m=n due to the orthogonality of mode shapes.

$$\overline{m} \frac{{d}^{2} {q}_{bn} ( t )}{{dt}^{2}} {\int }_{0}^{a} {\int }_{0}^{b} {\hat{Φ}}_{n}^{2} ( x , y ) dxdy + \overline{m} {\hat{ω}}_{bn}^{2} {q}_{bn} ( t ) {\int }_{0}^{a} {\int }_{0}^{b} {\hat{Φ}}_{n}^{2} ( x , y ) dxdy = {f}_{cjs} ( t ) {\int }_{0}^{a} {\int }_{0}^{b} {Φ}_{n} ( x , y ) δ ( x - vt + {d}_{s} , y - {y}_{js} ) dxdy \qquad ( 15 )$$

Rearranging eqn. (15) one obtains:

$$\frac{{d}^{2} {q}_{bn} ( t )}{{dt}^{2}} + {\hat{ω}}_{bn}^{2} {q}_{bn} ( t ) = \frac{{f}_{cjs} ( t ) {\int }_{0}^{a} {\int }_{0}^{b} {\hat{Φ}}_{n} ( x , y ) δ ( x - vt + {d}_{s} , y - {y}_{js} ) dxdy}{\overline{m} {\int }_{0}^{a} {\int }_{0}^{b} {\hat{Φ}}_{n}^{2} ( x , y ) dxdy} \qquad ( 16 )$$

Making the substation:

$${K}_{n} = {\int }_{0}^{a} {\int }_{0}^{b} {\hat{Φ}}_{n}^{2} ( x , y ) dxdy \qquad ( 17 )$$

and substituting equation (6),

$${k}_{vjs} = {m}_{vjs} {ω}_{vjs}^{2}$$

and manipulating the right-hand side of eqn. (16), the n^{th} modal equation of the bridge can be expressed as:

$$\frac{{d}^{2} {q}_{bn} ( t )}{{dt}^{2}} + {\hat{ω}}_{bn}^{2} {q}_{bn} ( t ) = {\sum }_{j = 1}^{s} {\sum }_{s = 1}^{na} \frac{{m}_{vjs} {\hat{Φ}}_{n} ( vt - {d}_{s} , {y}_{js} )}{{mK}_{n}} [ - g + {ω}_{vjs}^{2} {δ}_{js} ( t ) ] \qquad ( 18 )$$

where δⱼₛ(t) is the differential displacement between the js^{th} vehicle wheel system and the bridge and can be calculated from:

$${δ}_{js} ( t ) = {u}_{vjs} ( t ) - {\sum }_{n} {\hat{Φ}}_{m} ( vt - {d}_{s} , {y}_{js} ) {q}_{bm} ( t ) + {h}_{r} ( vt - {d}_{s} , {y}_{js} ) \qquad ( 19 )$$

and ωᵥⱼₛ is the vibration frequency of the js^{th} vehicle wheel system calculated from:

$${ω}_{vjs} = \sqrt{\frac{{k}_{vjs}}{{m}_{vjs}}} \qquad ( 20 )$$

Equations (3) and (18) form a coupled and nonlinear system of equations that characterize the dynamics of the bridge-vehicle system. This system can be solved using an iterative procedure. Different numerical convergence criteria can be used to accomplish a viable solution. In this implementation, it was found that the interaction force residuals and the bridge overall displacement shape provide suitable convergence and discretization parameters. The detailed procedure for the application of this method is presented in the next section.

It is common in previous studies to assume that the dynamic effects of a vehicle can be neglected if the vehicle mass in comparison to the bridge mass is negligible

$$( \frac{{m}_{v}}{\overline{m} L} ≪ 1 )$$

(Yang et al., 2004). However, it is clear from equation (18) that

$$\frac{{m}_{vjs}}{\overline{m}}$$

applies equally to both gravity and vehicle spring force terms. Instead, it can be seen from equation (18) that the contribution magnitude of the sprung mass is negligible only if α<<1 where α is defined as:

$$α = {ω}_{vjs}^{2} {δ}_{js} ( t ) / g$$

This criterion is not specific or limited to bridges subjected to light vehicles; this effect will be discussed in the next sections.

### Vehicle-Bridge Interaction Model Validation

### Implementation and Validation

The simulation method was validated through the Westfield Route 7 overpass (asset W475) bridge located in New Brunswick, Canada. The bridge is a 57 m long, three-span bridge constructed in 1986, consisting of six continuous, prestressed, AASHTO Type-III concrete girders as shown in FIG. 18a. FIG. 18b illustrates the overview of the instrumentation installed at W475; the details are described in MacLeod et. al (MacLeod et al., 2023). The instrumentation system consists of eight PCB Uniaxial Low-Frequency Industrial ICP accelerometers mounted on the bottom of the diaphragm where they join the exterior girders. They were sampled at 1024 Hz. These accelerometers were used for the estimation of the modal parameters of the bridge. Six BDI ST350 strain gauges with 610 mm extension bars were mounted on the web of the main girders near the bottom flange and at midspan. They were sampled at 1612 Hz. The bridge response collected using these sensors was used for the validation of the results evaluated by the method in this implementation. The data acquisition system consists of a National Instruments CompactRIO controller and a microprocessor computer.

### Modal Parameters Estimation

### Ambient Vibration Tests

The ambient vibration tests were performed on the bridge under operation. The acceleration time histories were collected over four hours and sampled at 1024 Hz frequency. The modal properties of the bridge were estimated using the Stochastic Subspace Identification Extended Unweighted Principal Component (SSI-UPCX) method implemented by ARTeMIS Modal software (Structural Vibrations Solutions, 2021). The spectral density was calculated by decimating to 25 Hz and using a block size of 4096 with 179 averages and 50% overlap resulting in a PSD estimate resolution of 0.006 Hz. The modes were estimated using model orders up to 90. The stabilization diagram and the first six estimated modes are shown in FIG. 19 and FIG. 20, respectively, where the estimated poles can be seen to quickly stabilize and provide clear mode shape estimates.

### Mode Shape Smoothening in the Longitudinal Direction

Considering the estimated mode shapes in FIG. 28, it can be noted that they are linear between the measurement points in both the longitudinal and transverse directions. These functions must be interpolated at the vehicle axle locations and the locations of interest for response analysis. Using the linear mode shapes with relatively coarse resolutions will result in errors since they are discontinuous in slope and curvature. Therefore, the mode shapes must be smoothened in the longitudinal direction. A study was conducted to evaluate the performance of several non-parametric smoothening methods including Fourier expansion, cubic spline interpolation, Piecewise Cubic Hermite Interpolating Polynomial (PCHIP) (Fritsch & Carlson, 1980) and Modified Akima piecewise cubic Hermite interpolation (Makima) (Akima, 1970). FIG. 21 shows the results of fitting the first mode in girder 1 using these methods.

The Fourier series expansion consisted of three terms to match the eight data points related to the sensor and support locations. Although the mode shape is analytically a trigonometric function, the Fourier expansion had significant overshooting of the peaks in the approach span and failed to properly capture the correct curvature. The spline, PCHIP and Makima methods perform different forms of piecewise cubic Hermite interpolation. Their difference is in how the slopes of the interpolant are calculated, leading to different behaviour for an area of flat, or undulating, data. The spline algorithm performs cubic interpolation to produce piecewise polynomials with continuous second-order derivatives and can capture the mode shape at midspan, however, suffers from overshoot at the approach spans. PCHIP does not overshoot the peaks but it is not guaranteed to have a continuous second derivative as seen between the midspan sensors, where it flattens the peak too aggressively. This also does not accurately describe the structural behaviour as there should only be one smooth local maximum, not two points. Finally, the Makima method preserves the shape of the mode, not overshooting or flattening the peaks, resulting in a mode that has a continuous second derivative while also sensible describing the structural behaviour. Based on this study, the Makima method was deemed to be suitable for smoothening and interpolation of the estimated mode shapes in the longitudinal direction.

### Mode Shape Expansion in the Transverse Direction

To highlight the importance of considering the full three-dimensional vibration behaviour of the bridge, two alternative simulation levels of increasing details were considered. First, the raw estimated mode shapes from the ambient vibration tests using two rows of accelerometers were considered. This results in capturing a linear transverse behaviour analogous to rigid body torsion. In the second analysis, the measured mode shapes were expanded using a finite element model of the bridge using the local correspondence principle method (Brincker et al., 2014). This allows for capturing a more refined transverse bending behaviour of the bridge. This can alternatively be accomplished by using a denser sensor network in the ambient vibration tests. FIG. 22a and FIG. 22b shows the paired estimated and FEM modes with excellent longitudinal agreement. However, it is evident two rows of sensors cannot capture the nonlinear transverse behaviour of mode shapes. The first six OMA modes were selected for the expansion using the paired dominant FEM modes shown in FIG. 22b. The expanded modes in FIG. 22c can be seen to better describe the nonlinear transverse bending of the structure. The expanded mode shapes were used in this implementation to represent higher resolution mode shapes that could be captured from ambient vibration tests using a finer mesh of measurement points. The natural frequencies from ambient vibration tests were used for the expanded modes.

### Simulation Process

The simulation was performed by solving equations (3) and (18) using an explicit Runge-Kutta (Dormand & Prince, 1986) formulation as implemented in MATLAB ode45 (The MathWorks, 2021). An iterative approach was employed to balance the interaction forces at the contact point of the vehicle and bridge systems. This was achieved when the norm of the change in displacement vectors of subsequent iterations reached a convergence criteria value of 0.01. The calculated displacement was converted to strain for comparison with the measured strain response. This was performed by taking the second derivative of the calculated displacement response and using 450 mm and 350 mm sensor offset with respect to the neutral axis for the interior and exterior girders, respectively.

Appropriate values for the vehicle and bridge parameters must be implemented when solving the coupled equations. These include the vehicle parameters of axle group spacings (d), vehicle width (w), wheel system mass (mᵥⱼₛ) which can be measured directly and wheel system frequencies (ωᵥⱼₛ), as well as the bridge mass (i) and road irregularities (hᵣ) which must be estimated. A 3-axle plow truck with a single front axle and rear 2-axle group was used as the test vehicle for the validation. The axle group spacing was measured to be 5.80 m with a width of 2.12 m and axle group weights of 67.5 KN and 177.2 KN for the first and second groups respectively. It was assumed that axle group weights are distributed evenly to each row of the vehicle model and were converted to the wheel system mass mᵥⱼₛ.

To determine the vehicle wheel system frequencies, six repeatable loading events at 100 km/h were analyzed. The loading events consisted of the vehicle travelling along the shoulder of the bridge and the strain time history of the far side girder was analyzed. Using the far girder resulted in amplified and isolated dynamic effects. The frequency spectrum of the strain response was calculated and the ensemble average with the resulting 95% confidence interval is shown in FIG. 23. The first prominent peak is approximately 0.43 Hz which corresponds to the driving frequency of the vehicle traversing the bridge. The second prominent frequency of 4.3 Hz corresponds to the first vehicle frequency, which is in agreement with values reported in the literature for similar vehicles. The dominant structural frequencies can be noted in FIG. 23 and may mask higher vehicle modes.

The bridge mass per unit area (m̅=ρh) was estimated to be 950 kg/m² based on construction drawings and material properties using an estimated typical concrete density of 2400 kg/m³. The road surface irregularities were modelled using ISO Standard 8608 (ISO 8608, 2016). Profiles were created based on road classifications of N, A, and B of ISO 8608, which correspond to no roughness, very good, and good road surfaces, respectively. These surfaces are generally representative of highway road conditions. As the actual road surface profile of the Westfield overpass is unknown and the generated profiles are random, it is not possible to simulate the exact specific profile. In this implementation, thirty simulations were calculated for each loading condition using randomly generated roughness profiles and the 95% confidence interval of the response is presented. Assuming that the road profile is random and stationary in nature, the measured response would be within the intervals created by an accurate probabilistic analysis for the studied road classifications.

### Results and Validation

To validate the accuracy of the proposed model in simulating the dynamic response of highway bridges under traffic loads, the method was compared against measured dynamic load tests on the Westfield overpass. The bridge was loaded with the New Brunswick Department of Transportation and Infrastructure (NBDTI) plow truck travelling at 100 km/h in three different lane positions on the shoulder, the middle of the traffic lane, and the center of the bridge. Three runs were considered in the Southbound travel direction for this analysis and the response of each girder was compared to the simulated girder response. In the following sections, the accuracy of the proposed model is validated and the effects of parameter a, transverse mode profile, number of modes, and road profile are discussed.

### Effect of Parameter Alpha

A study was conducted to determine the effect of parameter a on the vehicle contribution to the bridge dynamic response. The purpose was to illustrate that the effects of the vehicle dynamics can only be neglected if α<<1. The response of the bridge due to loading of just the first axle of the NBDTI plow truck travelling at 100 km/h was simulated using road profiles N and A. FIG. 24 shows the displacements of the bridge at the axle location, the wheel system, and differential acceleration term α. As seen in FIG. 24b, profile A introduces significant dynamic effects into the bridge response (uₐ) compared to profile N in FIG. 24a. This is caused by the large differential displacement between the vehicle and the bridge for profile A as the relatively stiff concrete bridge does not displace significantly compared to the lively truck. Considering the value for

$$\frac{{m}_{v}}{\overline{m} L} = 8.6 e - 3$$

is much less than one for both road profiles it is clear that the ratio of vehicle mass to bridge mass is not a good indicator for dynamic vehicle effects. However, considering the value for a, the smooth profile has a maximum value of 6.5e-3, which indicates very little dynamic vehicle effects, whereas the value for profile A is 7.3 and significantly larger than one, indicating significant dynamic effects. This validates that parameter α is a suitable indicator of whether dynamic vehicle effects are significant. This implementation also shows that road roughness and vehicle interaction can have a significant effect on the response of the structure. Therefore, considering the vehicle as a sprung mass that can capture this behaviour is essential and should be considered in cases where vehicle displacement is large relative to small bridge displacement, such as in concrete highway structures with surface irregularities.

### Effect of the Mode Shape Transverse Resolution

To determine the effect of the transverse resolution of the mode shapes on the simulation results, a study was conducted comparing the simulation results using linear, and nonlinear transverse mode shapes. To determine how well the simulation results globally compare to the measured response, Root Mean Square Error (RMSE) of the total bridge response considering all 30 simulation runs was calculated as shown in equation (22). Where N is the total number of data points, T is the number of simulation runs, xᵢⱼ is the estimated response at time i from simulation run j and mᵢ is the measured response.

$$RMSE = \sqrt{\frac{1}{N} {\sum }_{i = 1}^{N} \frac{1}{T} {\sum }_{j}^{T} {( {x}_{ij} - {m}_{i} )}^{2}} \qquad ( 22 )$$

The RMSE was calculated for a southbound vehicle travelling on the bridge shoulder, midlane, and the centerline and is summarized in Table 2. It can be noted that in all cases the nonlinear transverse modes produce less error than the linear transverse modes. Road profile A also results in lower error than profile B, which is expected due to the greater variation introduced with the increase in rough roughness.

TABLE 2
RMSE values comparison between nonlinear, and linear
transverse mode shapes for the total bridge response.

| | | | | RMSE (με) | | | |
|---|---|---|---|---|---|---|---|
| | | Shoulder | | Midlane | | Centerline | |
| Location | Mode Type | Prof A | Prof B | Prof A | Prof B | Prof A | Prof B |
| Total | Nonlinear | 1.31 | 2.36 | 1.22 | 2.10 | 1.29 | 2.13 |
| | Linear | 1.65 | 2.61 | 1.84 | 2.12 | 1.41 | 2.30 |

To determine the local fit of the estimated response to the measured response a Normalized Root Mean Square Error (NRSME) was calculated for each girder where mₘₐₓ and mₘᵢₙ are the maximum and minimum measured strain for each girder.

$$NRMSE = \frac{RMSE}{{m}_{max} - {m}_{min}} \qquad ( 23 )$$

The NRMSE was calculated for the response of each girder due to a southbound vehicle travelling on the bridge shoulder, midlane, and the centerline and is summarized in Table 3. Comparing the NRSME of each mode shape type, the error is comparable at the girders that correspond to loading locations; however, the error produced by the linear modes at girders further away from the loading location becomes very large compared to the nonlinear modes. This is because the mode shapes cannot describe the transverse nonlinear behaviour and the distribution of the loading at these locations.

TABLE 3
NRMSE values comparison between nonlinear, and linear
transverse mode shapes for each bridge girder.

| | | | | NRMSE (%) | | | |
|---|---|---|---|---|---|---|---|
| | | Shoulder | | Midlane | | Centerline | |
| Location | Mode Type | Prof A | Prof B | Prof A | Prof B | Prof A | Prof B |
| G1 | Nonlinear | 18 | 34 | 40 | 69 | 46 | 82 |
| | Linear | 19 | 33 | 53 | 78 | 82 | 122 |
| G2 | Nonlinear | 25 | 45 | 15 | 28 | 27 | 47 |
| | Linear | 29 | 48 | 16 | 27 | 27 | 48 |
| G3 | Nonlinear | 31 | 54 | 13 | 24 | 20 | 34 |
| | Linear | 40 | 63 | 12 | 20 | 14 | 26 |
| G4 | Nonlinear | 62 | 102 | 30 | 51 | 21 | 35 |
| | Linear | 88 | 130 | 26 | 43 | 15 | 28 |
| G5 | Nonlinear | 64 | 112 | 32 | 57 | 26 | 46 |
| | Linear | 100 | 160 | 45 | 71 | 30 | 53 |
| G6 | Nonlinear | 54 | 92 | 55 | 99 | 44 | 77 |
| | Linear | 61 | 110 | 124 | 181 | 85 | 129 |

The simulation results using transversely linear mode shapes for a southbound vehicle travelling on the bridge shoulder and centerline are shown in FIG. 25. Considering the shoulder position in FIG. 25a, the measured and estimated response of Girder 1, which is under the vehicle travel path, are in agreement. This agreement is expected as the load and mode measurement locations coincide for this girder. The response of the girders further away from the measurement locations results in a larger discrepancy in the estimated response. However, in general the proposed model outperforms a simplified beam model as the response dynamic characteristics are relatively captured along with the global torsional behaviour.

When the vehicle is travelling in the center of the bridge in FIG. 25b, the simulated results are in general less accurate in estimating the bridge response. This is because the bridge is loaded away from the measurement locations and due to the linear properties of the mode shapes in the transverse direction, it is not possible to adequately simulate the distribution of the response. This results in a uniform distribution with an equal contribution of each girder that both underestimates the maximum strain in Girder 3 and Girder 4, as well as overestimates the strain in the exterior Girder 1 and Girder 6. FIG. 26 shows the simulation results using the expanded transversely nonlinear mode shapes. It is evident using higher resolution mode shapes significantly improves the accuracy of the simulated response. In these simulations, the measured response is within the confidence intervals of the estimated response for all girders in any travelling scenarios of shoulder (FIG. 26a) or centerline (FIG. 26b). Overall, when using the proposed method, accounting for the true bridge mode shape transverse behaviour results in a better simulation of the bridge response.

### Effect of the Number of Mode Shapes

The cumulative contribution of each mode to the bridge displacement at midspan was analyzed to further compare the effect of the simulation level on the estimated response. It was found that depending on the position of the load, modes have significant differences in their contribution to the response for both linear and nonlinear transverse modes. When the vehicle load is on the shoulder, both the nonlinear and linear modes can capture the overall dominant torsional behaviour of the bridge as the response is dominated by the contribution of the second mode shape which is analogous to rigid body torsion. However, as the load moves to the centerline position in FIG. 27, the contribution of mode 2 is reduced and the difference between the estimated response using transversely nonlinear and linear mode shapes becomes more pronounced. Considering the centerline load, the response using the linear mode shapes results in the equal displacement of each girder with significant contributions from mode 1 and mode 5. These linear modes (FIG. 27b) result in a maximum displacement that is approximately 30% less than that from the nonlinear transverse modes (FIG. 27a) which closely resemble the expected displacement profile of the bridge. This is due to the significant contribution of mode 5, which reduces the displacement in Girder 1 and Girder 6 and increases the displacement in Girder 3 and Girder 4.

It is clear from this study that using the mode shapes of a beam to describe the bridge behaviour is insufficient as higher modes can have significant effects. The results in FIG. 27 also shows that it is not possible to assume that considering a limited number of modes will overestimate or underestimate the response. This is because of the three-dimensional nature of a bridge dynamic response, which results in the same mode to increase or decrease the response at different locations. Therefore, considering too few or simplified modes will result in an inaccurate estimation of the bridge dynamic response subjected to moving traffic loads.

### Effect of the Road Pavement Condition

In this implementation it was assumed that the shoulder and centerline pavement conditions are best described by road profile A whereas road profile B is a better fit for the mid-lane position. This was evaluated qualitatively and considering the magnitude of the bridge dynamic oscillations due to the vehicle travelling in each traffic path. This is also expected as the shoulder and centerline load path are rarely used during normal traffic. The conditions of the approach and bridge pavement surface for these positions are less worn than the rutting and significant roughness at the expansion joint in the wheel path of the mid-lane position.

The maximum mean estimated strain for each girder and the 95% confidence interval using both linear and transverse modes were compared against the measured data and are shown in FIG. 28. Three transverse load positions and two road surface profiles (A (FIG. 28a) and B (FIG. 28b)) were considered. A comparison between the maximum distributed loads across the girders using linear mode shapes shows that the accuracy of the bridge response estimation significantly decreases as the vehicle traffic path moves from the shoulder position to the centerline of the bridge. However, the expanded nonlinear transverse modes can accurately estimate the full bridge response for any traffic path and result in a very close fit between the simulated and measured response. The linear modes result in a poor estimation for the mid-lane and center position producing a flat distribution that significantly differs from the measured response. Considering the estimation of the mid-lane position using the expanded nonlinear transverse modes accurately reproduces the measured distribution, again showing that higher modes are necessary to capture the more complex transverse distribution of the load.

Analyzing the simulation's variance, it is apparent that the girder strains variance is highest in the girders nearest the vehicle and increases as the road roughness increases. This is because the road imperfections have the largest effect on the response locally, with the response of the girders further away being primary the dominant global behaviour of the bridge. These results demonstrate the large effect local surface imperfections such as corroded expansion joints or potholes can have on the overall maximum global response. Even the measured response for the centerline load position displays a higher degree of variation for load tests that were highly controlled and repeatable. This highlights that even small differences in velocity and position can result in significant differences in response due to vehicle bridge interaction. It also confirms that a viable VBI model must accurately account for vehicle dynamics and road roughness.

### Extension of Vehicle Bridge Interaction Model to BWIM System

List of Symbols

| | |
|---|---|
| Δ | Sum of the squares error |
| ∇⁴ | Biharmonic operator |
| a | Plate length |
| b | Plate width |
| c | Number of calibration events |
| D | Plate flexural rigidity |
| dₛ | Distance between the s^{th} and first axle |
| F | Number of Fourier terms |
| f_{cs} | Axle contact force |
| g | Number of girders |
| g | Acceleration due to gravity |
| h | Plate thickness |
| Hₛ | Multivariate Heaviside function |
| K | Measurement data segment length |
| l | Current Fourier series order |
| L | Estimated bridge curvature response matrix |
| L_{g} | Estimated girder curvature response |
| M | Dynamic influence line matrix for the bridge |
| m̅ | Plate mass per unit length |
| M_{g} | Dynamic influence line for the g^{th} girder |
| mₛ | Axle equivalent concentrated mass |
| na | Total number of axles |
| pₛ | Vehicle wheel system force |
| q_{bn} | Modal coordinates |
| ${q}_{n}^{F}$ | Fourier series approximated modal coordinates |
| qₛₕ | Homogenous part of modal coordinate solution for the s^{th} axle |
| qₛₚ | Particular part of modal coordinate solution for the s^{th} axle |
| R | Measured strain history matrix |
| \tilde{R} | Estimated strain response matrix |
| R_{g} | Measured girder strain history |
| tₚₛ | Time the s^{th} axle enters the bridge |
| t_{qs} | Time the s^{th} axle exits the bridge |
| ${\hat{u}}_{b}^{F}$ | Estimated bridge displacement |
| u_{b} | Vertical displacement of the bridge |
| v | Axle speed |
| W | Estimated axle weights |
| y̅ | Distance from neutral axis |
| γ | Unknown neutral axis location |
| δ | Dirac delta function |
| ε | Bending strain |
| ρ | Plate mass per unit areas |
| \hat{Φ}ₙ | Extracted mode shapes of the bridge |
| ${\hat{Φ}}_{n}^{F}$ | Fourier series mode shape approximation |
| Φₙ | Normal mode shapes |
| Ψ | Second partial derivative of the Fourier series approximated |
| | mode shapes |
| Ω | Fourier series fundamental frequency |
| \hat{ω}ₙ | Extracted natural frequencies of the bridge |
| ωₙ | Plate natural frequency |

The following section outlines the derivation of a parametric vehicle-bridge formulation suitable for BWIM applications. The bridge is modelled using an elastic plate with generalized geometry that is subjected to a series of vehicle axles moving at speed v as shown in FIG. 29a. The plate is assumed to follow classical plate theory and to have a constant cross-section with length a, width b, thickness h, mass per unit areas ρ, and flexural rigidity D. The bridge damping effects are neglected, and the support conditions and the number of bridge spans are arbitrary.

A multi-axle vehicle model is considered, where the axles are represented in one row of concentrated forces at the vehicle centerline. FIG. 29b shows dₛ is the distance between the s^{th} and first axle (d₁=0) with na being the total number of axles; mₛ is the axle equivalent concentrated mass. The equation of motion governing the transverse vibration of the bridge (Rao, 2006b) is:

$$m \frac{{\partial }^{2} {u}_{b} ( x , y , t )}{\partial {t}^{2}} + D ∇ {u}_{b} ( x , y , t ) = {\sum }_{s = 1}^{na} {p}_{s} ( x , y , t ) \qquad ( 24 )$$

where u_{b}(x,y,t) is the vertical displacement of the bridge, and pₛ(x,y,t) is the applied force acting on the bridge through the contact point of the s^{th} vehicle wheel system at location x=vt−dₛ, and y=yₛ measured from the bridge reference coordinate and m̅=ρh. The term ∇⁴ represents the biharmonic operator such that:

$${∇}^{4} = \frac{{\partial }^{4}}{\partial {x}^{4}} + 2 \frac{{\partial }^{4}}{\partial {x}^{2} \partial {y}^{2}} + \frac{{\partial }^{4}}{\partial {y}^{4}} \qquad ( 25 )$$

The force pₛ(x,y,t) can be expressed as:

$${p}_{s} ( x , y , t ) = {f}_{cs} δ ( x - vt + {d}_{s} , y - {y}_{s} ) \qquad ( 26 )$$

where δ(x−vt−dₛ, y−yₛ) is a 2D spatial Dirac delta function defined by:

$$\{ \begin{matrix}δ ( x - {x}_{0} , y - {y}_{0} ) = 0 for x \neq {x}_{0} \vert y \neq {y}_{0} \\ {\int }_{0}^{a} {\int }_{0}^{b} δ ( x - {x}_{0} , y - {y}_{0} ) dxdy = 1\end{matrix} \qquad ( 27 )$$

The contact force f_{cs}=−mₛg is the axle load as illustrated in FIG. 29b. The solution to equation (24) can be expressed in terms of a linear combination of the normal mode shapes Φₙ(x,y) and associated modal coordinates q_{bn}(t) as:

$${u}_{b} ( x , y , t ) = {\sum }_{n} {Φ}_{n} ( x , y ) {q}_{n} ( t ) n = 1 , 2 , … n \qquad ( 28 )$$

where the mode shapes are found by solving equation (29) and accounting for the intermediate and end boundary conditions:

$${∇}^{4} {Φ}_{n} ( x , y ) - {λ}_{n}^{4} {Φ}_{n} ( x , y ) = 0 \qquad ( 29 )$$

where

$${λ}_{n}^{4} = \overline{m} {ω}_{n}^{2} / D$$

and ωₙ is the bridge natural frequency. The mode shapes consist of multiple terms of trigonometric and hyperbolic functions where constants can be solved from the boundary conditions of each span. Classical solutions for simple cases can be found in (Rao, 2006b). For multiple span plate structures and complex boundary conditions, an analytical solution is cumbersome to develop. This implementation proposes a formulation that employs the extracted mode shapes \hat{Φ}ₙ(x,y) and natural frequencies \hat{ω}ₙ of the bridge using the modal testing of abridge where the “\hat{ }” denotes estimated values. Using the estimated mode shapes from the in-situ condition of a bridge structure allows the proposed solution in this paper to account for the bridge geometry, material properties, composite actions, connection effects and boundary conditions. Considering the estimated modal parameters and using equation (28), equation (24) can be rewritten as:

$$\overline{m} {\sum }_{n} {\hat{Φ}}_{n} ( x , y ) \frac{{d}^{2} {q}_{n} ( t )}{{dt}^{2}} + D {\sum }_{n} {∇}^{4} {\hat{Φ}}_{n} ( x , y ) {q}_{n} ( t ) = {\sum }_{s = 1}^{na} {f}_{cs} δ ( x - vt + {d}_{s} , y - {y}_{s} ) \qquad ( 30 )$$

Pre-multiplying both sides by \hat{Φ}ₘ(x,y), integrating over the overall bridge area, and using the orthogonality properties of mode shapes results in the following formulation for the n^{th} modal equation:

$$\frac{{d}^{2} {q}_{n} ( t )}{{dt}^{2}} + {\hat{ω}}_{n}^{2} {q}_{n} ( t ) = {\sum }_{s = 1}^{na} \frac{- {m}_{vs} g {\hat{Φ}}_{n} ( vt - {d}_{s} , {y}_{s} )}{\overline{m} {K}_{n}} \qquad ( 31 )$$

where

$${K}_{n} = {\int }_{0}^{a} {\int }_{0}^{b} {\hat{Φ}}_{n}^{2} ( x , y ) dxdy .$$

In order to develop a closed form solution to equation (31) which can be used in BWIM applications, the estimated discrete modes shapes must be represented analytically. This can be achieved by approximating the mode shape at coordinates yₛ and (vt−dₛ) using a Fourier Series as:

$${\hat{Φ}}_{n}^{F} ( vt - {d}_{s} , {y}_{s} ) = {\sum }_{l = 1}^{F} [ {a}_{0} + {b}_{l} sin ( l Ω ( vt - {d}_{s} ) ) + {a}_{l} cos ( sin ( l Ω ( vt - {d}_{s} ) ) ] \qquad ( 32 )$$

Where l=1 . . . F is the Fourier series order, Ω is the Fourier series frequency and a₀=0 for l>1. Dropping the terms dₛ and yₛ, and using ηₗ=lvΩ for brevity, equation (31) can be expressed as:

$$\frac{{d}^{2} {q}_{n}^{F} ( t )}{{dt}^{2}} + {\hat{ω}}_{n}^{2} {q}_{n}^{F} ( t ) = {\sum }_{s = 1}^{na} \frac{- {m}_{s} g}{\overline{m} {K}_{n}} {\sum }_{l = 1}^{F} [ {a}_{0} + {b}_{l} sin ( {η}_{l} t ) + {a}_{l} cos ( sin ( {η}_{l} t ) ] \qquad ( 33 )$$

where F is the number of Fourier terms. The solution to this differential equation is:

$${q}_{n}^{F} ( t ) = {\sum }_{s = 1}^{na} \frac{- {m}_{s} g}{\overline{m} {K}_{n} {\hat{ω}}_{n}} ( {q}_{sp} ( t ) + {q}_{sh} ( t ) ) \qquad ( 34 )$$

where qₛₚ and qₛₕ are the particular and homogenous parts of the solution for the s^{th} axle:

$${q}_{sp} ( t ) = {\sum }_{l = 1}^{F} [ \frac{α - {\hat{ω}}_{n}^{2} {a}_{l} cos ( {η}_{l} t ) - {\hat{ω}}_{n}^{2} {b}_{l} sin ( {η}_{l} t )}{{\hat{ω}}_{n} ( {η}_{l}^{2} - {\hat{ω}}_{n}^{2} )} ] \qquad ( 35 )$$

$${q}_{sh} ( t ) = {\sum }_{l = 1}^{F} [ \frac{α - {\hat{ω}}_{n}^{2} {a}_{l} cos ( {η}_{l} t ) - {\hat{ω}}_{n}^{2} {b}_{l} sin ( {η}_{l} t )}{{\hat{ω}}_{n} ( {η}_{l}^{2} - {\hat{ω}}_{n}^{2} )} ] \qquad ( 36 )$$

where

$$α = {a}_{0} {η}_{1}^{2} - {a}_{0} {\hat{ω}}_{n}^{2} .$$

Equation (35) represents the static deflection caused by moving axles while equation (36) represents the “fluctuating” dynamic component of the response, which is a function of the natural frequencies of the bridge, axle force, and velocity. The estimated bridge displacement can then be calculated as:

$$\begin{matrix}{\hat{u}}_{b}^{F} ( x , y , t ) = {\sum }_{n} [ {\hat{Φ}}_{n}^{F} ( x , y ) ( {q}_{n}^{F} ( t ) ) ] & n = 1 , 2 , ... n\end{matrix} \qquad ( 37 )$$

As most traditional BWIM systems rely on the measured bending strain in the girders, equation (37) is modified to represent bending strain at the distance from the neutral axis y:

$$ε ( x , y , t ) = \overline{y} {\sum }_{n} [ Ψ ( x , y ) ( {q}_{n}^{F} ( t ) ) ] \qquad ( 38 )$$

where the term Ψ(x,y) is the second partial derivative of the Fourier series approximation of the estimated mode shapes:

$$Ψ ( x , y ) = {\sum }_{l = 1}^{F} \frac{{\partial }^{2} {\hat{Φ}}_{n}^{F} ( x , y )}{\partial {x}^{2}} \qquad ( 39 )$$

### Extraction of Dynamic Influence Lines and Weighing Formulation

The data segment for a measured event is denoted as R and is a column vector consisting of the measured strain history for g girders with length K for each measurement.

$$R = {\{ \begin{matrix}{R}_{1} & {R}_{2} & ... & {R}_{g}\end{matrix} \}}^{T} \qquad ( 40 )$$

R must include the full time-history of the loading event from the time the first axle enters the bridge until the last axle leaves the bridge. To extract the influence line from a measured event it is necessary to ensure that the sampling frequency is sufficient for capturing all modes of interest.

Using the vehicle-bridge coupled formulation developed earlier, the estimated response, \tilde{R}, can be evaluated from:

$$\tilde{R} = L γ \qquad ( 41 )$$

where L={L₁(t) L₂(t) . . . L_{g}(t)}^{T} is the estimated response for all girders and is a column vector with (g×K) length. The constant γ=γ̅+∈ is introduced to account for an unknown neutral axis location (y̅) and errors ∈ due to measurement uncertainties. L_{g} is evaluated using equation (38) for each girder at the measurement location (x_{g}, y_{g}) as:

$${L}_{g} ( t ) = {\sum }_{n} [ Ψ ( {x}_{g} , {y}_{g} ) {\sum }_{s = 1}^{na} \frac{- {m}_{s} g}{\overline{m} {K}_{n} {\hat{ω}}_{n}} {H}_{s} ( {q}_{sp} ( t - {t}_{ps} ) + {q}_{sh} ( t - {t}_{ps} ) ) ] \qquad ( 42 )$$

where tₚₛ and t_{qs} are the time the s^{th} axle enter and exit the bridge respectively; Hₛ is a function of tₚₛ and t_{qs} and denotes the Multivariate Heaviside function to ensure the axles effects are only superimposed for the time they are travelling on the bridge.

$${H}_{s} = \{ \begin{matrix}0 & t - {t}_{ps} < 0 and {t}_{qs} - t < 0 \\ 1 & t - {t}_{ps} \geq 0 and {t}_{qs} - t \geq 0\end{matrix} \qquad ( 43 )$$

The sum of the squares error between the estimated response and measured response can be defined as:

$$Δ = {\sum }_{k = 1}^{K} {( R ( k ) - \tilde{R} ( k ) )}^{2} \qquad ( 44 )$$

which can be minimized using the least squares method resulting in:

$$γ = {( {L}^{T} L )}^{- 1} ( {L}^{T} R ) \qquad ( 45 )$$

In order to consider the data from multiple runs, the MLE approach (Gonçalves et al., 2021) is adopted. The maximum likelihood estimates for the parameter γ are obtained by solving the following equation for c calibration events:

$$γ = {( {\sum }_{i = 1}^{c} {L}_{i}^{T} {L}_{i} )}^{- 1} ( {\sum }_{i = 1}^{c} {L}_{i}^{T} {R}_{i} ) \qquad ( 46 )$$

Where Lᵢ varies for each calibration run and it depends on parameters such as vehicle speed, axle spacing, and axle weights. In the derivation of the influence line, axle weights were known quantities, therefore it is necessary for weighing purposes to reformulate equation (41) and isolate the axle weights. The measured response can be expressed as:

$$\tilde{R} = M W \qquad ( 47 )$$

where:

$$M = {[ \begin{matrix}{M}_{1} {( t , s )}^{T} & {M}_{2} {( t , s )}^{T} & … & {M}_{g} {( t , s )}^{T}\end{matrix} ]}^{T} \qquad ( 48 )$$

With M being a (K×g)×na matrix and M_{g} is the K×na matrix containing the dynamic influence line for the g^{th} girder. Each column is the dynamic influence line shifted to account for the lag that the s^{th} axle enters the bridge and is defined as:

$${M}_{g} ( t , s ) = γ {\sum }_{n} [ - \frac{Ψ ( {x}_{g} , {y}_{g} )}{\overline{m} {K}_{n} {\hat{ω}}_{n}} {H}_{s} ( {q}_{sp} ( t - {t}_{ps} ) + {q}_{sh} ( t - {t}_{ps} ) ) ] \qquad ( 49 )$$

where γ is calibrated using equation (46). The axle weights can then be estimated using the least squares method as:

$$W = {( {M}^{T} M )}^{- 1} ( {M}^{T} R ) \qquad ( 50 )$$

Where R is the measured strain history matrix as defined in equation (40) and M is the calibrated dynamic influence of the bridge calculated from equation (48). In full scale BWIM applications, accurate axle weight estimations are typically only possible for spans less than 10 m (Richardson et al. 2014) as it can be difficult to separate the contributions of individual axles from the total response of the structure. Accurate GVW estimations are still possible with medium to long span structures however, as the BWIM process is calculating the vehicle weight based on the measured signal which is itself the response of the bridge due to the total vehicle weight. To calculate GVW with the proposed method, the estimated axle weights from equation (50) can simply be summed. The model calibration and weighing procedures are summarized in FIG. 30.

### Validation of the Dynamic BWIM Method

The dynamic BWIM method was validated using the Westfield Route 7 overpass (asset W475) bridge located in New Brunswick, Canada. The bridge is a 57 m long, three-span bridge constructed in 1986, consisting of six continuous, prestressed, AASHTO Type-III concrete girders as shown in FIG. 18a. The system installed at W475 is described in detail by MacLeod et. al (MacLeod et al., 2023) with an overview of the instrumentation illustrated in FIG. 18b. The system consists of eight PCB Uniaxial Low-Frequency Industrial accelerometers mounted on the bottom of the diaphragms. These accelerometers were used for the estimation of the modal parameters of the bridge. Six BDI ST350 strain gauges with 610 mm extension bars were mounted on the web of the main girders at midspan. These sensors were used as the weighing sensors for the calibration and validation of the proposed method. The data acquisition system was a National Instruments CompactRIO.

### Modal Parameters Estimation

The modal parameters of the bridge were estimated using Stochastic Subspace Identification Extended Unweighted Principal Component (SSI-UPCX) with ARTeMIS Modal Pro software (Structural Vibrations Solutions, 2021). The acceleration time history length was four hours in duration sampled at a frequency of 1024 Hz. The spectral density was calculated by decimating to 25 Hz and using a block size of 4096 with 179 averages and a 50% overlap resulting in a PSD estimate resolution of 0.006 Hz. The modes were estimated using model orders up to 90 and the stabilization diagram and the first six estimated modes are shown in FIG. 31.

A Modified Akima piecewise cubic Hermite interpolation (Makima) (Akima, 1970) method was used for interpolating the estimated mode shapes in the longitudinal direction. It was found essential to use accurate transverse bending modes to accurately model the three-dimensional dynamic response of a structure. As the proposed BWIM method is based on three-dimensional plate theory, the measured modes were expanded using a finite element model of the bridge using the local correspondence principle method as outlined in (Brincker et al., 2014) to achieve more refined transverse bending mode shapes. This can also be accomplished by using a denser sensor network that can describe the full transverse behaviour of the bridge.

### Validation Field Tests

The dynamic BWIM method was validated using a series of field tests on the Westfield case study bridge. The normal traffic was redirected to off/on ramps allowing for a large volume of test runs and vehicle configurations to be tested. Two trucks provided by the New Brunswick Department of Transportation and Infrastructure (NBDTI) were used: A 2-axle utility truck (FIG. 32a) and a 3-axle plow truck. Additional runs were completed with the 3-axle plow truck towing a loaded 2-axle trailer as shown in FIG. 32b. This resulted in three different vehicle configurations for studying the effects of vehicle characteristics on the weighing algorithm. Details of the test vehicles are summarized in Table 4.

TABLE 4
Vehicle information for the calibration

| | | | Gross Vehicle |
|---|---|---|---|
| Vehicle ID | Vehicle Description | Axles | Weight (KN) |
| A2-45 | Utility Truck | 2 | 44.7 |
| A3-185 | Plow Truck | 3 | 184.7 |
| A5-260 | Plow Truck + Trailer | 5 | 257.8 |

The field tests used to validate the dynamic BWIM method consisted of a total of 78 runs. Five different transverse positions were considered including: North Shoulder (NS), North Lane (NL), Centerline (CL), South Lane (SL), and South Shoulder (SS). Three different test velocities were set at 70 km/h, 90 km/h and the maximum velocity that can be achieved by the test vehicles within the allowable speed limit. For A2-45 this was 110 km/h, while for A3-185 and A5-260 this was 100 km/h due to the capabilities of the vehicles. The exact velocities were measured with a radar speed gun as the vehicle crossed the bridge. A subset of test runs was chosen, as summarized in Table 5, to isolate the effects of lane position, vehicle configuration and velocity on GVW estimation.

TABLE 5
Validation run subset categories

| Subset | Parameter | # Runs | Direction | Position | Velocity |
|---|---|---|---|---|---|
| Overall | Overall | 78 | All | All | All |
| Vehicle | A2-45 | 14 | All | Midlane | All |
| Configuration | A3-185 | 14 | All | Midlane | All |
| | A5-260 | 14 | All | Midlane | All |
| Velocity | Max Speed | 18 | All | Midlane | Max Speed |
| | 90 Kph | 12 | All | Midlane | 90 km/h |
| | 70 Kph | 12 | All | Midlane | 70 km/h |
| Transverse | North Shoulder (NS) | 9 | North | Shoulder | Max Speed |
| Position | North Lane (NL) | 21 | North | Midlane | All |
| | Centerline (CL) | 18 | All | Centerline | Max Speed |
| | South Lane (SL) | 21 | South | Midlane | All |
| | South Shoulder (SS) | 9 | South | Shoulder | Max Speed |

### Validation of Results

### Extracted Influence Lines

Theoretically, influence lines extracted considering distinct vehicle combinations should represent the true structural behaviour, regardless of the vehicle used. If the vehicle behaviour is too dominant, however, the vehicle effects can significantly influence the extracted influence line. To investigate the sensitivity of the proposed parametric dynamic model to vehicle characteristics two loading situations were considered. First, a standard vehicle travelling at different velocities was studied. Second, different vehicles were considered travelling with the same velocity. The girder specific dynamic influence lines were created by calibrating the model for a single loading event and then simulating the response to a unit load. An influence line for each loading event was also extracted using the traditional Matrix Method for comparison.

In general, when observing the influence lines extracted using the Matrix Method there is significant variation among the results whereas the girder specific influence lines produced with the calibrated parametric dynamic model are very consistent. Considering the effect of vehicle velocity, it is clear from FIG. 33a and FIG. 33b that the Matrix Method incorporates the dynamic oscillations into the response due to the large fluctuations in the extracted influence lines that vary at each velocity. However, as the dynamic fluctuations in the signal become reduced at 70 km/hr the matrix method influence lines approach the expected true static influence line. Conversely, velocity is a parameter in the dynamic parametric model, therefore it is successful in extracting a very similar influence surface for each loading event regardless of vehicle speed and associated dynamic vehicle effects.

Considering the effects of vehicle configuration on influence line extraction shown in FIG. 34a and FIG. 34b, the Matrix Method again produces significantly variable influence lines and tends to incorporate the unique dynamic effects of each vehicle. This is evident as the influence line extracted using each vehicle have very different characteristics where they should be the same since the structural response characteristics should remain unchanged. This could introduce significant errors in weighing different vehicle configurations as the extracted influence lines are not representative of the generic structural response. The dynamic method can successfully isolate the structural response from the vehicle effects regardless of the vehicle used for the loading.

In general, this implementation supports the conclusions of Gonçalves et al. (Gonçalves et al., 2021) that fitting a parametric model instead of numerically fitting the specific influence line ordinates is less susceptible to incorporating aspects of the measured signal which are not the true bridge structural response. This is because the Matrix Method is unbound in how the influence line is fit and simply produces a discrete curve which best fits the measured signal, making it unable to separate the structural response from vehicle effects and more likely to overfit the response and include unwanted effects. The parametric dynamic model is fitting the full simulated response of the structure to the measured response and therefore is constrained within the bounds of the model. As such it is better able to isolate the desired structural response from undesired effects not included in the model.

### Mode Shapes Approximation Using Fourier Expansion

The effect of the number of Fourier terms included in the expansion of the mode shapes on the GVW estimation is discussed in this section. The first six modes evaluated at girder 2 are compared in FIG. 35 for one and eight Fourier terms. When only one term is considered in the mode shape approximation, the fit of the symmetric mode shapes is close to the measured mode shape, however, the fit of the asymmetric mode shapes deviates significantly. When eight Fourier terms are considered in the series approximation, the fit of the mode shapes matches very closely to the measured mode shapes.

To determine the effects of the number of Fourier terms considered in the approximation on the accuracy of GVW estimation a study was performed considering weighing vehicles in the mid-lane and the shoulder. For both transverse positions, the model was calibrated using vehicle A5-260 travelling in the middle of the lane. The GVW was then calculated using an increasing number of Fourier series terms and is shown in FIG. 36, which shows the error in GVW considering the number of Fourier terms used in the mode shape approximation. Considering weighing vehicles in the mid-lane position, acceptable results are achieved with one Fourier term with generally similar error and a slight reduction in variance considering more terms. Considering weighing in the shoulder position, however, the number of Fourier terms has a pronounced effect on the GVW estimation accuracy. The accuracy significantly increases by accounting for a greater number of Fourier terms for at least six terms. This is due to weighing on the shoulder requiring an accurate representation of the transverse behaviour of the bridge structure due to the pronounced torsional, and higher mode effects compared to the center of the bridge which is mostly dominated by the first bending mode. This makes the shoulder position much more sensitive to the quality of the mode shape fit. Based on the results of this implementation, a total of eight Fourier terms were used for all subsequent analyses.

### Calibration Vehicle

To determine the effect of the calibration vehicle parameters on GVW estimation, the system was calibrated using runs in the mid-lane position including all velocities considering each vehicle configuration separately and considering all vehicles combined. The calibrated model was then used to estimate the GVW of the vehicles in the mid-lane position for all velocities with the results shown in FIG. 37 which shows the GVW error for each individual vehicle considering the vehicle used for the calibration procedure listed on the x-axis. The mean absolute error, mean bias error, standard deviation (SD), and total analytical error (TAE), where TAE=Bias+2SD, for both weight, and relative values were calculated to evaluate the calibration sets and are summarized in Table 6.

Generally, all calibration sets perform well with mean absolute errors between 3.9 KN and 4.8 KN. This performance is to be expected based on the robustness of the model calibration considering the vehicle characteristics that were outlined previously. Calibrating with A2-45 results in very accurate GVW estimations for A2-45 and overall, the least bias error and bias. However, it introduces significant error in the heavier vehicles and has the largest variance of the calibration sets leading to the most TAE of any calibration set. Considering A5-260 as the calibration vehicle resulted in the lowest TAE of 10.2 KN and the lowest mean absolute error of 3.7 KN making it the highest performing calibration set. Having the lowest TAE in terms of KN is the best indicator of performance for GVW estimation as it includes both the mean absolute error and variance of the estimates; therefore, A5-260 was selected as the calibration vehicle for all subsequent studies. Compared to the same analysis performed using the Moses algorithm as seen in Table 7, the proposed method has significantly less TAE in all cases. The Moses algorithm produces much more variable error between calibration vehicle types due to the nonparametric method overfitting the vehicle induced dynamic effects.

The effect of calibration sets on the value of γ coefficient was also investigated and is summarized in Table 6. As the coefficient has a physical meaning based on the geometry of the bridge and the sensor location, the value of γ should theoretically be the same for all calibration runs. The values of the coefficient for the A3-185, A5-260 and all calibration sets show very little variation whereas the value for A2-45 is approximately 25 mm smaller. This aligns with the dissimilar GVW results of set A2-45 in FIG. 37. Considering the travelling direction of the vehicle, the same value for γ is estimated for the heavier vehicles A3-185 and A5-260 showing robustness in the method to ignore vehicle-induced effects caused by different approach conditions. The difference between the North and South directions for the lightweight A2-45 likely contributes to the higher variance in GVW estimation. All estimated values of γ are a reasonable location of the neutral axis above the sensor considering the geometry and dimensions of the girder.

TABLE 6
GVW estimation results for all vehicles considering calibration data sets.

| | A2-45 | | A3-185 | | A5-260 | | All | |
|---|---|---|---|---|---|---|---|---|
| Parameter | (KN) | (%) | (KN) | (%) | (KN) | (%) | (KN) | (%) |
| Mean Absolute Error | 3.9 | 2.7% | 4.8 | 4.5% | 3.7 | 3.7% | 4.0 | 3.9% |
| Mean Bias Error | 2.0 | 0.2% | −4.2 | −4.2% | −2.8 | −3.2% | −3.2 | −3.5% |
| Standard Deviation | 5.7 | 3.5% | 3.9 | 3.2% | 3.7 | 3.3% | 3.8 | 3.3% |
| Total Analytical Error | 13.4 | 7.0% | 12.0 | 6.5% | 10.2 | 6.6% | 10.7 | 6.5% |

| Direction | γ (mm) | γ (mm) | γ (mm) | γ (mm) |
|---|---|---|---|---|
| South | 456 | 483 | 480 | 480 |
| North | 466 | 484 | 479 | 479 |

TABLE 7
GVW estimation using the Moses algorithm for all
vehicles considering calibration data sets

| | A2-45 | | A3-185 | | A5-260 | | All | |
|---|---|---|---|---|---|---|---|---|
| Parameter | (KN) | (%) | (KN) | (%) | (KN) | (%) | (KN) | (%) |
| Mean Absolute Error | 10.4 | 7.0% | 4.6 | 3.9% | 13.4 | 8.0% | 5.2 | 4.3% |
| Mean Bias Error | 5.6 | 2.5% | 1.6 | −1.0% | 12.9 | 6.9% | 2.6 | −0.8% |
| Standard Deviation | 13.8 | 7.9% | 6.4 | 5.5% | 12.3 | 5.5% | 6.8 | 5.8% |
| Total Analytical Error | 33.1 | 18.2% | 14.4 | 12.0% | 37.6 | 17.9% | 16.2 | 12.3% |

### Vehicle Velocity and Dynamic Amplification Factor

To investigate the sensitivity of the proposed method to vehicle dynamics, a study was performed to determine the relationships between vehicle configuration, dynamic amplification factor (DAF), velocity, and GVW estimation error. It is shown in FIG. 38 that as the velocity decreases, there is less variance in the results, however, a similar average error is achieved for all velocities. This is supported by the ability of the proposed method to extract a very similar influence surface for each loading event regardless of vehicle speed. Velocity does not show a correlation with DAF as there can be high and low DAF values for the same velocity depending on the vehicle characteristics as seen in FIG. 38. The same vehicle configuration can also have very different DAF values depending on the velocity as well as the approach conditions of the bridge structure. Considering the effect of DAF on GVW estimation it can be noted that DAF is affected by two components: contributions from the moving load effects, and the contributions from the vehicle bridge interaction effects. It is seen by the flat spread of the data that the DAF does not have a significant effect on the accuracy of the GVW estimation. It can therefore be concluded that the proposed parametric method can account for the bridge response from the moving load component in the context of BWIM while being insensitive to the variable effects introduced by the vehicle bridge interaction. However, overall, the proposed method was found to produce reasonably accurate GVW estimations for vehicles travelling at various speeds with variable dynamic amplifications.

### Bridge Torsional and Transverse Bending Behaviour

To evaluate the optimum number of modes that must be considered in the proposed parametric dynamic method for an accurate GVW estimation, BWIM was conducted using one and six modes. It is known that vehicle-bridge coupled dynamic behaviour is complex and it is necessary to consider the torsional and transverse bending behaviour of the bridge structure to estimate an accurate response. To determine the effect of the number of modes on GVW estimations, the system was calibrated with A5-260 in the South Lane, North Lane and North Shoulder and the vehicles were then weighed for all transverse positions. As seen in FIG. 39, when the weighing is performed in the same lane as the calibration models using one mode and six modes produce comparably good results. The same is also true for the opposite lanes due to bridge symmetry. This is to be expected as the case of only the first mode being locally calibrated for that transverse position is similar to classic BWIM methods. The results are also equally successful for vehicles travelling in the centerline as there is little contribution from torsional or transverse bending modes in the center of the bridge, making the simple beam mode an adequate approximation. It can be noted that the variation in the error is larger in the centerline position compared to the lane position when one mode is used and is largest overall when using 6 modes. This is due to the location of the accelerometers which are located along the outside girders of the bridge, therefore, the system has less errors in the transverse positions closer to those locations. The mode shape ordinates from the center of the bridge are estimated through the FEM modal expansion which may introduce errors compared to the measured values. Considering weighing vehicles travelling on the shoulder, however, using one mode results in large errors, whereas using six modes still results in accurate GVW estimates.

The ability of the proposed method to describe the transverse behaviour of the bridge is more apparent when the system is calibrated using the traffic travelling on bridge shoulder. The GVW estimations for a system calibrated using the North Shoulder transverse position are shown in FIG. 40. It is clear that using the first mode only results in accurate results for weighing vehicles in the same transverse position as the calibration runs, however, there is significant error when weighing in the other transverse positions. Using six mode shapes, however, accurate estimations are obtained for all transverse positions. It can therefore be concluded that the inclusion of the transverse bending and torsional bridge behaviour through higher modes enables the calibration of the system in one transverse position to be adequate to achieve successful GVW estimates in all other transverse positions. This can be very advantageous for numerous reasons as it can allow for fewer calibration runs to be performed, has the potential for the proposed method to be used for multiple presence events and reduces the sensitivity to the transverse position. These advantages are valuable in expanding the current BWIM systems to more bridge applications while providing improved accuracy and efficiency.

### REFERENCES

Akima, H. (1970). A New Method of Interpolation and Smooth Curve Fitting Based on Local Procedures. Journal of the ACM, 17(4), 589-602. https://doi.org/10.1145/321607.321609
Algohi, B., Mufti, A., & Thomson, D. (2018). Detection of Speed and Axle Configuration of Moving Vehicles Using Acoustic Emission. Journal of Civil Structural Health Monitoring, 8(3), 353-362. https://doi.org/10.1007/s13349-018-0281-8
ASCE. (2021). Report Card for America's Infrastructure: A Comprehensive Assessment of America's Infrastructure.
Brincker, R., Skafte, A., López-Aenlle, M., Sestieri, A., D'Ambrogio, W., & Canteli, A. (2014). A local correspondence principle for mode shapes in structural dynamics. Mechanical Systems and Signal Processing, 45(1), 91-104. https://doi.org/10.1016/j.ymssp.2013.10.025
Brown, A. J. (2011). Bridge Weigh-in-Motion Deployment Opportunities in Alabama. University of Alabama.
Canadian Society of Civil Engineers. (2016). Canadian Infrastructure Report Card: Informing the Future. 1-164.
Carraro, F., Gonçalves, M. S., Lopez, R. H., Miguel, L. F. F., & Valente, A. M. (2019). Weight estimation on static B-WIM algorithms: A comparative study. Engineering Structures, 198. https://doi.org/10.1016/j.engstruct.2019.109463
Chan, T. H. T., Law, S. S., Yung, T. H., & Yuan, X. R. (1999). An Interpretive Method for Moving Force Identification. Journal of Sound and Vibration, 219(3), 503-524. https://doi.org/10.1006/jsvi.1998.1904
Deng, L., & Cai, C. S. (2010). Identification of Dynamic Vehicular Axle Loads: Theory and Simulations. JVC/Journal of Vibration and Control, 16(14), 2167-2194. https://doi.org/10.1177/1077546309351221
Dormand, J. R., & Prince, P. J. (1986). A reconsideration of some embedded Runge-Kutta formulae. Journal of Computational and Applied Mathematics, 15(2), 203-211. https://doi.org/i0.1016/0377-0427(86)90027-0
Dowling, J., O'Brien, E. J., & González, A. (2012). Adaptation of Cross Entropy optimisation to a dynamic Bridge WIM calibration problem. Engineering Structures, 44(November), 13-22. https://doi.org/10.1016/j.engstruct.2012.05.047
Fritsch, F. N., & Carlson, R. E. (1980). Monotone Piecewise Cubic Interpolation. SIAM Journal on Numerical Analysis, 17(2), 238-246. https://doi.org/10.1137/0717021
Gonçalves, M. S., Carraro, F., & Lopez, R. H. (2021). A B-WIM algorithm considering the modeling of the bridge dynamic response. Engineering Structures, 228(July 2020), 111533. https://doi.org/10.1016/j.engstruct.2020.111533
González, A., Rowley, C., & O'Brien, E. J. (2008). A General Solution to the Identification of Moving Vehicle Forces on a Bridge. International Journal for Numerical Methods in Engineering, 75(3), 335-354. https://doi.org/10.1002/nme.2262
Hibbeler, R. C. (2018). Structural Analysis. In TA-TT-(Tenth edit). Pearson Education, Inc. https://doi.org/LK—https://worldcat.org/title/975362663
Ieng, S., Zermane, A., Schmidt, F., & Jacob, B. (2012). Analysis of B-WIM Signals Acquired in Millau Orthotropic Viaduct Using Statistical Classification. Proceedings of the International Conference on Weigh-In-Motion (ICWIM 6), December 2015, 43-52.
Ieng, S.-S. (2015). Bridge Influence Line Estimation for Bridge Weigh-in-Motion System. Journal of Computing in Civil Engineering, 29(1), 06014006. https://doi.org/10.1061/(asce)cp.1943-5487.0000384
ISO 8608. (2016). Mechanical vibration—Road surface profiles—Reporting of measured data. E, 44.
Jacob, B. (1999). WAVE-European research project on weigh-in-motion. Proceedings of the Final Symposium of the Project WAVE (1996-1999), 15-29.
Jacob, B., & O'Brien, E. J. (1998). European Specification on Weigh-in-Motion of Road Vehicles (COST323). Second European Conference on Weigh-in-Motion of Road Vehicles, June 2020, 171-183.
Kalin, J., Žnidarič, A., & Lavrič, I. (2006). Practical Implementation of Nothing-on-the-Road Bridge Weigh-in-Motion System. Proc., 9th Int. Symp. on Heavy Vehicle Weights and Dimensions, 207, 3-10.
Law, S. S., Chan, T. H. T., & Zeng, Q. H. (1997). Moving Force Identification: A Time Domain Method. Journal of Sound and Vibration, 201(1), 1-22. https://doi.org/10.1006/jsvi.1996.0774
Law, S. S., Chan, T. H. T., & Zeng, Q. H. (1999). Moving Force Identification—A Frequency and Time Domains Analysis. Journal of Dynamic Systems, Measurement, and Control, 121(3), 394-401.
Lydon, M., Robinson, D., Taylor, S. E., Amato, G., O'Brien, E. J., & Uddin, N. (2017). Improved Axle Detection for Bridge Weigh-in-Motion Systems Using Fiber Optic Sensors. Journal of Civil Structural Health Monitoring, 7(3), 325-332. https://doi.org/10.1007/si3349-017-0229-4
Lydon, M., Taylor, S. E., Robinson, D., Mufti, A., & Brien, E. J. O. (2016). Recent developments in bridge weigh in motion (B-WIM). Journal of Civil Structural Health Monitoring, 6(1), 69-81. https://doi.org/10.1007/s13349-015-0119-6
MacLeod, E., Wyman, B., Matthews, J., & Arjomandi, K. (2023). Proceedings of the Canadian Society of Civil Engineering Annual Conference 2021. In S. Walbridge, M. Nik-Bakht, K. T. W. Ng, M. Shome, M. S. Alam, A. El Damatty, & G. Lovegrove (Eds.), CSCE International Structural Specialty Conference (Vol. 241). Springer Nature Singapore. https://doi.org/10.1007/978-981-19-0511-7
McNulty, P., & O'Brien, E. J. (2003). Testing of Bridge Weigh-In-Motion System in a Sub-Arctic Climate. Journal of Testing and Evaluation, 31(6), 11686. https://doi.org/10.1520/JTE12377J
Moses, F. (1979). Weigh-in-Motion System Using Instrumented Bridges. Transportation Engineering Journal of ASCE, 015(3), 233-249.
Mustafa, S., Sekiya, H., Hirano, S., & Miki, C. (2020). Iterative Linear Optimization Method for Bridge Weigh-in-Motion Systems Using Accelerometers. Structure and Infrastructure Engineering, 0(0), 1-12. https://doi.org/10.1080/15732479.2020.1802490
O'Brien, E. J., Quilligan, M. J., & Karoumi, R. (2006). Calculating an influence line from direct measurements. Proceedings of the Institution of Civil Engineers: Bridge Engineering, 159(1), 31-34. https://doi.org/10.1680/bren.2006.159.1.31
O'Brien, E. J., Zhang, L., Zhao, H., & Hajializadeh, D. (2018). Probabilistic bridge weigh-in-motion. Canadian Journal of Civil Engineering, 45(8), 667-675. https://doi.org/10.1139/cjce-2017-0508
O'Brien, E. J., Žnidarič, A., & Dempsey, A. T. (1999). Comparison of Two Independently Developed Bridge Weigh-in-Motion Systems. International Journal of Heavy Vehicle Systems, 6(1), 147-161.
O'Connor, C., & Chan, T. H. T. (1988). Dynamic Wheel Loads From Bridge Strains. Journal of Structural Engineering, 114(8), 1703-1723. https://doi.org/10.1061/(ASCE)0733-9445(1988)114:8(1703)
Ojio, T., Carey, C. H., O'Brien, E. J., Doherty, C., & Taylor, S. E. (2016). Contactless Bridge Weigh-in-Motion. Journal of Bridge Engineering, 21(7). https://doi.org/10.1061/(asce)be.1943-5592.0000776
Quilligan, M. (2002). Development and Testing of a 2-Dimensional Multi-Vehicle Bridge-WIM Algorithm Development and Testing of a 2-Dimensional Multi-Vehicle Bridge-WIM Algorithm. Third International Conference on Weigh-in-Motion (ICWIM3).
Rao, S. S. (2006a). Vibration of Continuous Systems. John Wiley & Sons, Inc. https://doi.org/10.1002/9780470117866
Rao, S. S. (2006b). Vibration of Continuous Systems. John Wiley & Sons, Inc. https://doi.org/10.1002/9780470117866
Richardson, J., Jones, S., Brown, A., O'Brien, E., & Hajializadeh, D. (2014). On the Use of Bridge Weigh-in-Motion for Overweight Truck Enforcement. International Journal of Heavy Vehicle Systems, 21(2). https://doi.org/10.1504/IJHVS.2014.061632
Rowley, C. W., O'Brien, E. J., Gonzalez, A., & Žnidarič, A. (2009). Experimental testing of a moving force identification bridge weigh-in-motion algorithm. Experimental Mechanics, 49(5), 743-746. https://doi.org/10.1007/s11340-008-9188-3
Sekiya, H. (2019). Field Verification over One Year of a Portable Bridge Weigh-in-Motion System for Steel Bridges. Journal of Bridge Engineering, 24(7). https://doi.org/10.1061/(asce)be.1943-5592.0001411
Sekiya, H., Kubota, K., & Miki, C. (2018). Simplified Portable Bridge Weigh-in-Motion System Using Accelerometers. Journal of Bridge Engineering, 23(1). https://doi.org/10.1061/(asce)be.1943-5592.0001174
Structural Vibrations Solutions. (2021). ARTeMIS Modal 7.1.0.0.
The MathWorks. (2021). MATLAB 2021a Release.
WAVE. (2001). Weighing-in-Motion of Axles and Vehicles for Europe (WAVE): Report of Work Package 1.2. Work.
Yang, Y. B., Lin, C. W., & Yau, J. D. (2004). Extracting bridge frequencies from the dynamic response of a passing vehicle. Journal of Sound and Vibration, 272(3-5), 471-493. https://doi.org/10.1016/50022-460X(03)00378-X
Yu, Y., Cai, C. S., & Deng, L. (2016). State-of-the-Art Review on Bridge Weigh-in-Motion Technology. Advances in Structural Engineering, 19(9), 1514-1530. https://doi.org/10.1177/1369433216655922
Zhao, H., Uddin, N., O'Brien, E. J., Shao, X., & Zhu, P. (2014). Identification of Vehicular Axle Weights with a Bridge Weigh-in-Motion System Considering Transverse Distribution of Wheel Loads. Journal of Bridge Engineering. https://doi.org/10.1061/(ASCE)BE.1943-5592.0000533
Zhao, H., Uddin, N., Shao, X., Zhu, P., & Tan, C. (2015). Field-calibrated influence lines for improved axle weight identification with a bridge weigh-in-motion system. In Structure and Infrastructure Engineering (Vol. 11, Issue 6, pp. 721-743). Taylor & Francis. https://doi.org/10.1080/15732479.2014.904383

1. A computer-implemented method for monitoring vehicular traffic on a bridge, comprising the steps of:
receiving digital data representing the response of the bridge to a traffic event on the bridge, where the digital data has been collected during the traffic event, from displacement sensors and accelerometers mounted on the superstructure of the bridge, wherein
the digital data from the displacement sensors embody bending responses of the bridge,
the digital data from the accelerometers embody acceleration responses of the bridge, and
the digital data from the displacement sensors and the digital data from the accelerometers are synchronised in the same time space,
providing a parametric model which uses modal parameters to simulate generalized boundary conditions and two-dimensional behaviour of the bridge;
using the parametric model to process the digital data to solve for deformation of the bridge and characteristics of the vehicle traffic, and
generating an output that describes the deformation of the bridge and characteristics of the vehicle traffic.

2. The method of claim 1, wherein the estimated modal parameters are generated from digital data collected from the displacement sensors and accelerometers mounted when there is no traffic event on the bridge.

3. The method of claim 2, wherein the parametric model further comprises a coupled moving mass vehicle-bridge model and wherein the bridge modal parameters are represented parametrically as a Fourier series.

4. The method of claim 2, wherein the modal parameters embody torsional and transverse behaviour of the bridge in response to the traffic event.

5. The method of claim 3, wherein the displacement sensors comprise strain sensors.

6. The method of claim 3, further comprising reformulating the parametric model and solving the reformulated parametric model to obtain the parameters of a vehicle traveling on the bridge during the traffic event.

7. The method of claim 6, wherein the vehicle parameters are selected from the group consisting of the gross weight of the vehicle, the weight of each axle of the vehicle, the spacing of the axles on the vehicle, the number of axles of the vehicle, the speed of the vehicle, and the direction of travel of the vehicle.

8. The method of claim 1, wherein the parametric model is expressed as the non-linear differential equation:
$$\frac{{d}^{2} {q}_{bn} ( t )}{{dt}^{2}} + {\hat{ω}}_{bn}^{2} {q}_{bn} ( t ) = {\sum }_{j = 1}^{s} {\sum }_{s = 1}^{na} \frac{{m}_{vjs} {\hat{Φ}}_{n} ( vt - {d}_{s} , {y}_{js} )}{\overline{m} {K}_{n}} [ - g + {ω}_{vjs}^{2} {δ}_{js} ( t ) ]$$
wherein
dₛ is distance between the s^{th} and first axle
g is acceleration due to gravity
j is wheel row
Kₙ is modal integral defined as:
$${\int }_{0}^{a} {\int }_{0}^{b} {\hat{Φ}}_{n}^{2} ( x , y ) dxdy$$
m̅ is plate mass per unit length
mᵥⱼₛ is equivalent concentrated mass at each vehicle degree of freedom
q_{bn} is bridge response in modal coordinates
t is time measured from beginning of loading event
v is axle speed
yⱼₛ is transverse wheel position measured from the bridge coordinate reference
δⱼₛ is differential displacement between the vehicle wheel system and the bridge
\hat{Φ}ₙ is extracted mode shapes of the bridge
\hat{ω}_{bn} is extracted natural frequencies of the bridge
ωᵥⱼₛ is vibration frequency of the vehicle wheel system.

9. The method of claim 8, wherein the deformation of the bridge in modal coordinates is derived by solving for q_{bn}.

10. The method of claim 9, wherein the deformation of the bridge in geometric coordinates is derived by performing a linear transformation operation on the equation of claim 8 and solving for vertical displacement of the bridge.

11. The method of claim 9, wherein the deformation of the bridge in geometric coordinates is derived by solving for û_{b} in equation:
$${\hat{u}}_{b} ( x , y , t ) = {\sum }_{n} {\hat{Φ}}_{n} ( x , y ) {q}_{bn} ( t )$$
wherein
û_{b} is estimated vertical displacement of the bridge

| | |
|---|---|
| \hat{Φ}ₙ | is extracted mode shapes of the bridge |
| q_{bn} | is bridge response in modal coordinates. |

12. The method of claim 11, further comprising relating the displacement of the bridge to one or more of the gross weight of the vehicle, the weight of each axle of the vehicle, the spacing of the axles on the vehicle, the number of axles of the vehicle, the speed of the vehicle, and the direction of travel of the vehicle.

13. A system monitoring of vehicle traffic on a bridge, comprising:
displacement sensors and accelerometers mounted on the superstructure of the bridge and configured to collect digital data associated with a bending response and acceleration response of at least a part of the superstructure,
a data acquisition module for receiving the digital data and
a computer processing module programmed with instructions to
solve a parametric model which uses modal parameters to simulate generalized boundary conditions and two-dimensional behaviour of the bridge to process the digital data to solve for deformation of the bridge and characteristics of the vehicle traffic, and
an output module for generating an output that describes the deformation of the bridge and characteristics of the vehicle traffic.

14. The system of claim 13, wherein the estimated modal parameters are generated from digital data collected from the displacement sensors and accelerometers mounted when there is no traffic event on the bridge.

15. The system of claim 14, wherein the parametric model further comprises a coupled moving mass vehicle-bridge model and wherein the bridge modal parameters are represented parametrically as a Fourier series.

16. The system of claim 14, wherein the modal parameters embody torsional and transverse behaviour of the bridge in response to the traffic event.

17. The system of claim 15, wherein the displacement sensors comprise strain sensors.

18. The system of claim 15, further comprising reformulating the parametric model and solving the reformulated parametric model to obtain the parameters of a vehicle traveling on the bridge during the traffic event.

19. The system of claim 18, wherein the vehicle parameters are selected from the group consisting of the gross weight of the vehicle, the weight of each axle of the vehicle, the spacing of the axles on the vehicle, the number of axles of the vehicle, the speed of the vehicle, and the direction of travel of the vehicle.

20. The system of claim 13, wherein the parametric model is expressed as the non-linear differential equation:
$$\frac{{d}^{2} {q}_{bn} ( t )}{{dt}^{2}} + {\hat{ω}}_{bn}^{2} {q}_{bn} ( t ) = {\sum }_{j = 1}^{s} {\sum }_{s = 1}^{na} \frac{{m}_{vjs} {\hat{Φ}}_{n} ( vt - {d}_{s} , {y}_{js} )}{\overline{m} {K}_{n}} [ - g + {ω}_{vjs}^{2} {δ}_{js} ( t ) ]$$
wherein
dₛ is distance between the s^{th} and first axle
g is acceleration due to gravity
j is wheel row
Kₙ is modal integral defined as:
$${\int }_{0}^{a} {\int }_{0}^{b} {\hat{Φ}}_{n}^{2} ( x , y ) dxdy$$
m̅ is plate mass per unit length
mᵥⱼₛ is equivalent concentrated mass at each vehicle degree of freedom
q_{bn} is bridge response in modal coordinates
t is time measured from beginning of loading event
v is axle speed
yⱼₛ is transverse wheel position measured from the bridge coordinate reference
δⱼₛ is differential displacement between the vehicle wheel system and the bridge
\hat{Φ}ₙ is extracted mode shapes of the bridge
\hat{ω}_{bn} is extracted natural frequencies of the bridge
ωᵥⱼₛ is vibration frequency of the vehicle wheel system.

21. The system of claim 20, wherein the deformation of the bridge in modal coordinates is derived by solving for q_{bn}.

22. The system of claim 21, wherein the deformation of the bridge in geometric coordinates is derived by performing a linear transformation operation on the equation of claim 8 and solving for vertical displacement of the bridge.

23. The system of system claim 21, wherein the deformation of the bridge in geometric coordinates is derived by solving for û_{b} in equation:
$${\hat{u}}_{b} ( x , y , t ) = {\sum }_{n} {\hat{Φ}}_{n} ( x , y ) {q}_{bn} ( t )$$
wherein
û_{b} is estimated vertical displacement of the bridge

| | |
|---|---|
| \hat{Φ}ₙ | is extracted mode shapes of the bridge |
| q_{bn} | is bridge response in modal coordinates. |

24. The system of claim 23, further comprising relating the displacement of the bridge to one or more of the gross weight of the vehicle, the weight of each axle of the vehicle, the spacing of the axles on the vehicle, the number of axles of the vehicle, the speed of the vehicle, and the direction of travel of the vehicle.
